(19) United States
(12) Patent Application Publication
(10) Pub. No.: US 2026/0198298 A1
(43) Pub. Date: Jul. 9, 2026

(54) SEMICONDUCTOR DEVICES HAVING ETCH STOP STRUCTURE AND DATA STORAGE SYSTEMS INCLUDING THE SAME

(71) Applicant: SAMSUNG ELECTRONICS CO., LTD., Suwon-si (KR)

(72) Inventors: Seiwoong PARK, Suwon-si (KR); Sunil SHIM, Suwon-si (KR); Youngjin JUNG, Suwon-si (KR); Juneon JIN, Suwon-si (KR)

(73) Assignee: SAMSUNG ELECTRONICS CO., LTD., Suwon-si (KR)

(21) Appl. No.: 19/386,547

(22) Filed: Nov. 12, 2025

(30) Foreign Application Priority Data
Jan. 6, 2025 (KR) 10-2025-0001618

(51) Int. Cl. H01L 23/528; H01L 23/00; H01L 25/18; H10B 43/10; H10B 43/27; H10B 43/35; H10D 80/30

(52) U.S. Cl. CPC H10W 20/435; H10B 43/10; H10B 43/27; H10B 43/35; H10D 80/30; H10W 20/43; H10W 90/00; H10W 90/792

(57) ABSTRACT

A semiconductor device is provided. The device includes: a stack structure with interlayer insulating layers and gate electrodes; an upper interconnection structure below the stack structure; an upper bonding structure connected to the upper interconnection structure and bonded to the lower bonding structure; a channel structure; etch stop structures in an upper portion of the stack structure, the etch stop structures extending along a second direction, perpendicular to the first direction, and spaced apart along a third direction, perpendicular to the first direction and the second direction, within the first region; a common source conductive layer on the stack structure between the etch stop structures; and a buffer layer on the common source conductive layer.

### CROSS-REFERENCE TO RELATED APPLICATION

This application claims priority to Korean Patent Application No. 10-2025-0001618, filed on Jan. 6, 2025, in the Korean Intellectual Property Office, the disclosure of which is incorporated herein by reference in its entirety.

### BACKGROUND

The present disclosure relates to semiconductor devices and data storage systems including the same.

A semiconductor device may be used to store a large amount of data in a data storage system. Accordingly, a method for increasing the data storage capacity of a semiconductor device has been researched. For example, as one method for increasing the data storage capacity of a semiconductor device, a semiconductor device including memory cells arranged three-dimensionally, instead of memory cells arranged two-dimensionally, has been proposed.

### SUMMARY

One or more example embodiments provide a semiconductor device having improved miniaturization and reliability.

One or more example embodiments also provide a data storage system including a semiconductor device having improved miniaturization and reliability.

According to an aspect of an example embodiment, a semiconductor device, includes: a first semiconductor structure including a first substrate, circuit elements on the first substrate, a lower interconnection structure connected to the circuit elements, and a lower bonding structure connected to the lower interconnection structure; and a second semiconductor structure on the first semiconductor structure. The second semiconductor structure includes: a stack structure including interlayer insulating layers and gate electrodes stacked along a first direction, within a first region and a second region; an upper interconnection structure below the stack structure; an upper bonding structure connected to the upper interconnection structure and bonded to the lower bonding structure; a channel structure including a first portion penetrating the stack structure along the first direction and a second portion extending upwardly from the first portion within the first region; etch stop structures in contact with an upper portion of the stack structure, the etch stop structures extending along a second direction, perpendicular to the first direction, and spaced apart along a third direction, perpendicular to the first direction and the second direction, within the first region; a common source conductive layer on the stack structure between the etch stop structures within the first region, the common source conductive layer being connected to the second portion of the channel structure; and a buffer layer on the common source conductive layer.

According to another aspect of an example embodiment, a semiconductor device, includes: a stack structure including interlayer insulating layers and gate electrodes stacked along a first direction, within a first region and a second region; separation regions penetrating the stack structure along the first direction, the separation regions extending along a second direction, perpendicular to the first direction, and spaced apart along a third direction, perpendicular to the second direction, within the first region and the second region; a channel structure penetrating the stack structure along the first direction, within the first region; etch stop structures on the stack structure, the etch stop structures extending along the second direction within the first region; a common source conductive layer on the stack structure between the etch stop structures and connected to a channel layer of the channel structure, within the first region; and a buffer layer on the common source conductive layer and including an insulating material. An upper surface of the buffer layer is on a same level as an upper surface of the etch stop structures.

According to another aspect of an example embodiment, a semiconductor device, includes: a stack structure comprising interlayer insulating layers and gate electrodes stacked along a first direction, within a first region and a second region; separation regions penetrating the stack structure along the first direction, the separation regions extending along a second direction, perpendicular to the first direction, and spaced apart along a third direction, perpendicular to the second direction, within the first region and the second region; a channel structure penetrating the stack structure along the first direction, within the first region; etch stop structures on the stack structure, the etch stop structures extending along the second direction within the first region; a protective layer on the stack structure within the second region; a common source conductive layer on the stack structure between the etch stop structures and connected to a channel layer of the channel structure, within the first region; and a buffer layer on the common source conductive layer and comprising an insulating material. An upper surface of the common source conductive layer is on a same level as an upper surface of the etch stop structures. At least one of the etch stop structures comprises an end connected to the protective layer and extends along the second direction from the protective layer.

According to another aspect of an example embodiment, a method of manufacturing a semiconductor device, includes: forming a molded structure by stacking interlayer insulating layers and sacrificial insulating layers in a first direction, within a first region and a second region on a substrate; forming channel structures penetrating through the molded structure in the first direction within the first region; forming separation openings penetrating through the molded structure in the first direction, extending in a second direction, perpendicular to the first direction, and spaced apart from each other in a third direction, perpendicular to the second direction, within the first region and the second region; forming a stack structure by replacing the sacrificial insulating layers with gate electrodes through the separation openings and filling the separation openings to form separation regions; transferring the stack structure onto a carrier substrate to remove the substrate exposed to an upper portion and forming a preliminary insulating layer in the first region and the second region; dry-etching the preliminary insulating layer to form etch stop structures extending in the second direction and spaced apart from each other in the third direction, within the first region; forming a preliminary common source conductive layer covering the etch stop structures and connected to a channel layer of the channel structure, within the first region; forming a preliminary buffer layer disposed on the preliminary common source conductive layer; and performing etching up to an upper surface of the etch stop structures by planarizing the preliminary buffer layer and the preliminary common source insulating layer.

In a structure in which two or more substrate structures are bonded, a protective layer may be formed on an extension region on a stack structure exposed from a rear surface of an upper substrate structure, and a common source line may be formed in a cell region. In this case, when planarizing the common source line and an insulating layer thereon in the cell region, as an etch stop layer, an etch stop structure may be formed as a portion of the protective layer. The insulating layer formed to be high as an upper portion of the protective layer on the cell region may be etched, thereby enabling miniaturization of the device. Additionally, a plurality of etch stop structures may be disposed in the cell region to prevent dishing during a planarization process.

Additionally, by applying H-rich nitride as a protective layer, hydrogen may be provided to the channel structure, thereby easily performing activation of each channel layer.

Advantages and effects of the present disclosure are not limited to the foregoing content and may be more easily understood in the process of describing a specific example embodiment of the present disclosure.

### BRIEF DESCRIPTION OF DRAWINGS

The above and other aspects, features, and advantages will be more apparent from the following description of example embodiments, taken in conjunction with the accompanying drawings, in which:

FIG. 1 is a schematic plan view of a semiconductor device according to example embodiments;

FIG. 2 is a partially enlarged view of a semiconductor device according to example embodiments;

FIGS. 3A and 3B are schematic cross-sectional views of a semiconductor device according to example embodiments;

FIGS. 4A and 4B are enlarged views of a partial region of FIG. 3B;

FIGS. 5 to 7 are enlarged views of a semiconductor device according to example embodiments;

FIGS. 8 and 9 are schematic plan views of a semiconductor device according to example embodiments;

FIGS. 10A, 10B, 10C, 10D, 10E, 10F, 10G, 10H, 10I, 10J, 10K, 10L and 10M are schematic cross-sectional views illustrating a method of manufacturing a semiconductor device according to example embodiments;

FIG. 11 is a view schematically illustrating a data storage system including a semiconductor device according to example embodiments; and

FIG. 12 is a perspective view schematically illustrating a data storage system including a semiconductor device according to an example embodiment.

### DETAILED DESCRIPTION

Hereinafter, example embodiments will be described with reference to the accompanying drawings. Hereinafter, the terms ‘above,’ ‘upper portion,’ ‘upper surface,’ ‘below’, ‘lower portion,’ ‘lower surface,’ ‘side surface,’ and the like, may be understood as being indicated based on the accompanying drawing, except that they are indicated by drawing references and referred to separately. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another example embodiment also provided herein or not provided herein but consistent with the present disclosure.

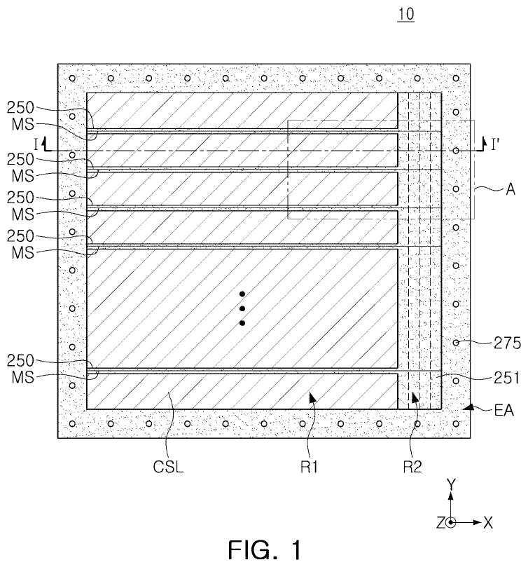

Hereinafter, a semiconductor device according to an example embodiment will be described with reference to FIGS. 1 to 4B.

FIG. 1 is a schematic plan view of a semiconductor device according to example embodiments.

A semiconductor device 10 may include a first semiconductor structure S1 and a second semiconductor structure S2, and the first semiconductor structure S1 may be stacked in a Z-direction, a vertical direction with respect to the second semiconductor structure S2. Specifically, the first semiconductor structure S1 may be disposed below the second semiconductor structure S2 in the Z-direction. Example embodiments are not limited thereto, and the second semiconductor structure S2 may be disposed below the first semiconductor structure S1.

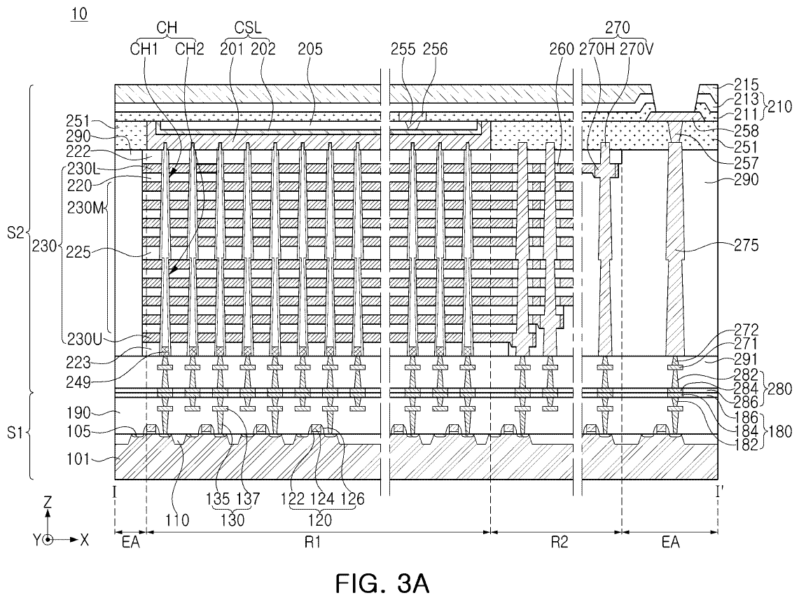

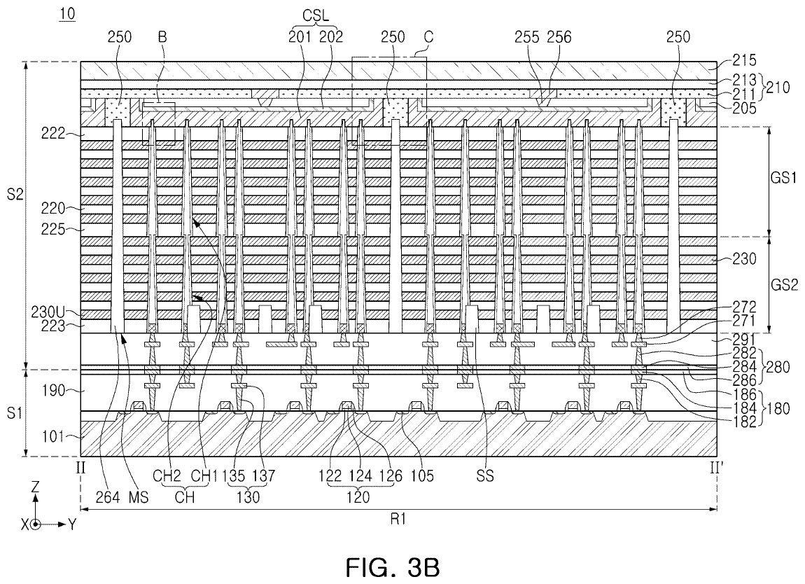

In an example embodiment, the semiconductor device 10 may include a peripheral circuit structure PERI (see FIGS. 3A and 3B) which is a first semiconductor structure S1 in which a peripheral circuit region is formed on a first substrate 101, and a memory cell structure CELL (see FIGS. 3A and 3B) which is a second semiconductor structure S2 including a common source line CSL.

In an example embodiment, the first semiconductor structure S1 may form a peripheral circuit by forming transistors and metal patterns for wiring the transistors on the first substrate 101. After the peripheral circuit is formed on the first semiconductor structure S1, the second semiconductor structure S2 may be formed, but example embodiments are not limited thereto.

The semiconductor device 10 may include a cell region R1 in an X-direction and an extension region R2 to at least one side of the cell region R1.

The cell region R1 is a memory cell region in which memory cells are disposed, and may be a region in which channel structures CH are disposed. The extension region R2 may correspond to a region for electrically connecting the memory cells to the peripheral circuit structures PERI, and may be a region in which gate electrode layers extend by different lengths for this purpose, but example embodiments are not limited thereto.

Edge regions EA may be disposed on each side of the semiconductor device 10. The edge region EA may be disposed on an outer side of the extension region R2 and in an upper portion, a side portion, and a lower portion of the cell region R1, and may be a region including an upper capping layer 290 without a gate electrode. The edge region EA may be defined as a region in which a pad region connected from the outside is disposed, external contact vias 275 connected to the pad region are disposed, or various through-vias connected to the first semiconductor structure S1 are disposed. In FIG. 1, it is illustrated that the edge region EA is disposed on each side to have a frame shape, but example embodiments are not limited thereto.

A protective layer 251 may be disposed within the extension region R2, and the protective layer 251 may cover the extension region R2 and the edge region EA and may be disposed in a plate type.

A plurality of etch stop structures 250 may be disposed within the cell region R1. The etch stop structures 250 may extend within the cell region R1 in the X-direction and may be spaced apart from each other in a Y-direction. The etch stop structures 250 may be disposed in parallel. The etch stop structures 250 may have the same material and the same height as the protective layer 251, and may be connected to each other at boundaries between the cell region R1 and the extension region R2, and boundaries between the cell region R1 and the edge region EA.

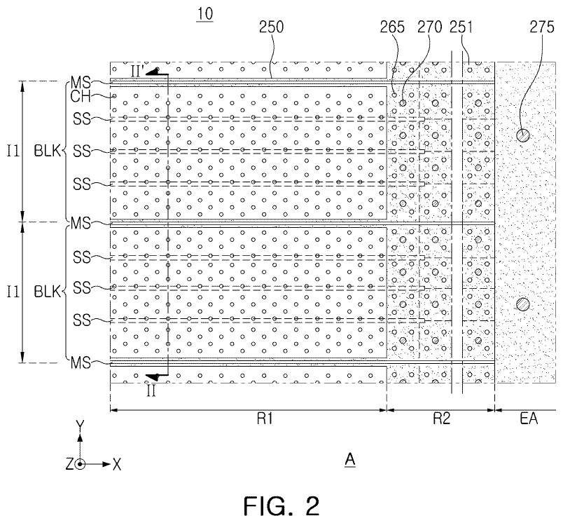

Accordingly, the etch stop structures 250 may have a comb shape extending from the protective layer 251 toward the cell region R1 as illustrated in FIG. 1 and FIG. 2, but example embodiments are not limited thereto.

The cell region R1 may be divided into a plurality of regions by the protective layer 251 and the etch stop structure 250.

The common source line CSL may be disposed in each of the plurality of regions of the cell region R1. The common source line CSL may be disposed to have a plate shape in each of the plurality of regions, and may be physically spaced apart from a common source lines CSL of a plurality of adjacent regions.

A nitride film, specifically, a silicon nitride film, e.g., an H-rich SiN which is a nitride film including a large amount of hydrogen, may be applied to the protective layer 251 and the etch stop structure 250. The H-rich SiN may be applied as Plasma enhanced-SiN (PE-SiN) or the like, and is a material layer having significantly low thermal conductivity, high energy absorption, and minimal thermal stress change. The H-rich SiN may function as a buffer layer. During a melting laser annealing (MLA) process of the semiconductor layer included in the common source line CSL, because selective processing is not possible, energy and heat may be transmitted into the extension region R2 and the edge region EA in which a large amount of lower interconnection lines are formed, and thus, element defects may occur due to unintended metal migration of a copper material forming the lower interconnection lines. Accordingly, the protective layer 251 may be disposed on the extension region R2 and the edge region EA to minimize the influence to a lower portion thereof and protect the lower interconnection lines while performing crystallization and planarization of the semiconductor layer of the cell region R2 through the melting laser annealing process.

Each of the etch stop structures 250 may have a bar shape or a line shape having a predetermined width on an X-Y plane, and the predetermined width may be 3 to 5 times a width of an upper end of the channel structure CH. For example, the etch stop structure 250 may have a width of 300 nm to 500 nm, preferably 300 nm to 400 nm, but example embodiments are not limited thereto.

When the etch stop structures 250 are disposed in the cell region R1, and the common source line CSL and a buffer layer 205 thereon are thickly formed over an entire region and then planarized, the etch stop structures 250 may function as an etch stop layer, so that dishing of the common source line CSL and the buffer layer 205 disposed over a large area may be prevented.

Hereinafter, example embodiments will be described in more detail with reference to FIGS. 2 to 4B.

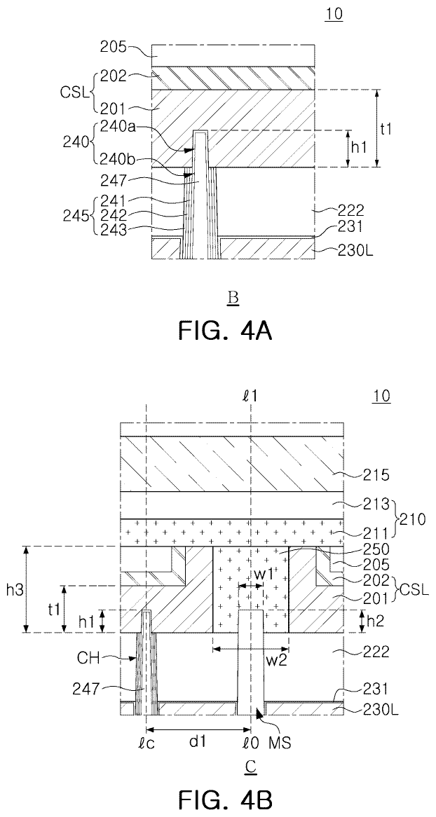

FIG. 2 is a partially enlarged view of a semiconductor device according to example embodiments, FIGS. 3A and 3B are schematic cross-sectional views of a semiconductor device according to example embodiments, and FIGS. 4A and 4B are partially enlarged views of a semiconductor device according to example embodiments. FIG. 2 is an enlarged view of part ‘A’ of FIG. 1, and FIGS. 3A and 4B illustrate cross-sections along cutting lines I-I′ and II-II′ of FIGS. 1 and 2, respectively. FIGS. 4A and 4B are enlarged views of part ‘B’ and part ‘C’ of FIG. 3B, respectively.

Referring to FIGS. 2 to 4B, the semiconductor device 10 may include a first semiconductor structure S1 defined as a peripheral circuit structure PERI and a second semiconductor structure S2 defined as a memory cell structure CELL on the first semiconductor structure S1. The first semiconductor structure S1 and the second semiconductor structure S2 may be bonded to each other through bonding structures 180 and 280.

The first semiconductor structure S1 may include a first substrate 101, circuit elements 120 on the first substrate 101, a lower interconnection structure 130, a lower bonding structure 180, and a lower capping layer 190.

The first substrate 101 may include a semiconductor material, such as a group IV semiconductor, a group III-V compound semiconductor, or a group II-VI compound semiconductor. The first substrate 101 may be provided as a bulk wafer or an epitaxial layer. An active region may be defined by element isolation layers 110 in the first substrate 101. Source/drain regions 105 including impurities may be disposed in a portion of the active region.

The circuit elements 120 may include transistors. Each of the circuit elements 120 may include a circuit gate dielectric layer 122, a circuit gate electrode 124, a spacer layer 126, and a source/drain region 105. The source/drain regions 105 including impurities may be disposed in the first substrate 101 on both sides of the circuit gate electrode 124. The spacer layers 126 may be disposed on both sides of the circuit gate electrode 124. The circuit gate dielectric layer 122 may include silicon oxide, silicon nitride, or a high-κ material. The circuit gate electrode 124 may include at least one of doped silicon, titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). For example, the circuit gate electrode 124 may include a doped polycrystalline silicon layer. According to an example embodiment, the circuit gate electrode 124 may be formed of two or more multilayers.

The lower interconnection structure 130 may be electrically connected to the circuit gate electrodes 124 of the circuit elements 120 and the source/drain regions 105. The lower interconnection structure 130 may include lower contact plugs 135 and lower interconnection lines 137 in which at least one region thereof has a line shape. Some of the lower contact plugs 135 may be connected to the source/drain regions 105, and, the others of the lower contact plugs 135 may be connected to the gate electrodes 124. The lower contact plugs 135 may electrically connect the lower interconnection lines 137 disposed on different levels from an upper surface of the first substrate 101 to each other. The lower interconnection structure 130 may include a conductive material, and may include, for example, tungsten (W), copper (Cu), and aluminum (Al), and each of the components may further include a diffusion barrier including at least one of titanium (Ti), titanium nitride (TiN), tantalum (Ta), tantalum nitride (TaN), or tungsten nitride (WN). According to example embodiments, the number of layers and the arrangement of the lower contact plugs 135 and the lower interconnection lines 137 included in the lower interconnection structure 130 may be variously changed.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, and may include, for example, tungsten (W), copper (Cu), and aluminum (Al), and each of the components may further include a diffusion barrier. The lower bonding insulating layer 186 may also function as a diffusion barrier of the lower bonding pad 184 and may include at least one of silicon oxide, silicon nitride, silicon oxynitride, or silicon oxycarbide. The lower bonding insulating layer 186 may have a thickness thinner than a thickness of the lower bonding pad 184, but example embodiments are not limited thereto. The lower bonding structure 180 may be in direct contact with and bonded or connected to an upper bonding structure 280 by hybrid bonding. For example, the lower bonding pad 184 may be in contact with and may be bonded to an upper bonding pad 284 by copper-to-copper bonding, and the lower bonding insulating layer 186 may be in contact with and may be bonded to an upper bonding insulating layer 286 by dielectric-to-dielectric bonding. The lower bonding structure 180 may provide an electrical connection path between the first semiconductor structure S1 and the second semiconductor structure S2 along with the upper bonding structure 280.

The lower capping layer 190 may be disposed on the first substrate 101 to cover the circuit elements 120 and the lower interconnection structure 130. The lower capping layer 190 may include a plurality of insulating layers. The lower capping layer 190 may include an insulating material, such as silicon oxide, silicon nitride, silicon oxynitride, or silicon oxycarbide.

The second semiconductor structure S2, which is a memory cell structure, may include, within the cell region R1 (i.e., a memory cell region), a first conductive layer 201, a second conductive layer 202 on an upper surface of the first conductive layer 201, a buffer layer 205 on an upper surface of the second conductive layer 202, gate electrodes 230 stacked on a lower surface of the first conductive layer 201 and disposed in the cell region R1 and the extension region R2, interlayer insulating layers 220 alternately stacked with the gate electrodes 230, channel structures CH disposed to penetrate through the gate electrodes 230, separation regions MS extending in one direction by penetrating through the gate electrodes 230, and insulating regions SS penetrating through a portion of the gate electrodes 230. The second semiconductor structure S2 may surround the cell region R1 and the extension region R2 and may include an edge region EA, and may include an upper capping layer 290 within the edge region EA. The second semiconductor structure S2 may include a protective layer 251 disposed horizontally to the first conductive layer 201 on a lowermost interlayer insulating layer 222 in the extension region R2 and the edge region EA, and may further include an upper capping layer 290 covering the gate electrodes 230, and an upper insulating structure 210 and a passivation layer 215 on a buffer layer 205 and the protective layer 251.

The second semiconductor structure S2 may include studs 272 for electrical connection with the first semiconductor structure S1, an upper interconnection structure 271 below stack structures GS1 and GS2, and an upper bonding structure 280 connected to the upper interconnection structure 271.

The second semiconductor structure S2 may further include support structures 265 within the extension region R2, contact plugs 270, and external contact vias 275 within the edge region EA.

As illustrated in FIG. 3A, the cell region R1 may be a region in which gate electrodes 230 are spaced apart from each other and stacked in a vertical direction, for example, the Z-direction, and channel structures CH are disposed. The extension region R2 may be disposed on at least one side of the cell region R1 in the X-direction, and may be a region in which the contact plugs 270 connected to the gate electrodes 230, respectively, are disposed to electrically connect the memory cells to the first semiconductor structure S1. In FIGS. 2 and 3A, the gate electrodes 230 are illustrated as extending by different lengths so that contact pads are formed for connection between the respective gate electrodes 230 and contact plugs 270, but example embodiments are not limited thereto.

The edge region EA may be disposed outside the extension region R2 and outside the cell region R1. Pad regions 258 for transmitting and receiving signals from the outside may be disposed in the edge region EA. The external contact vias 275 for transmitting signals from the outside to the first semiconductor structure S1 may be disposed in the edge region EA. The edge region EA is a region in which the gate electrodes 230 do not extend and the upper capping layer 290 is disposed, and may be connected to the lower first semiconductor structure S1 in a state in which the external contact vias 275 are insulated from gate electrodes 230.

In the cell region R1, the extension region R2, and the edge region EA the upper insulating structure 210 may be disposed on the stack structures GS1 and GS2, and the passivation layer 215 may be disposed in an upper portion of the upper insulating structure 210.

The gate electrodes 230 may be vertically spaced apart and stacked on the lower surface of the first conductive layer 201 and the protective layer 251 to form the stack structures GS1 and GS2 together with the interlayer insulating layers 220. The stack structures GS1 and GS2 may include a plurality of stack structures GS1 and GS2 vertically stacked. In FIGS. 3A and 3B, lower and upper stack structures GS1 and GS2 are illustrated as being included, but not limited thereto, and 3 to 5-stage stack structures GS1 to GSn may be included. However, according to example embodiments, the stack structures GS1 to GSn may be formed as a single stack structure.

The gate electrodes 230 may include at least one lower gate electrode 230L of a gate of a ground select transistor, memory gate electrodes 230M of a plurality of memory cells, and upper gate electrodes 230U of gates of string select transistors. Here, the lower gate electrode 230L and the upper gate electrodes 230U may be referred to as “lower” and “upper” based on a direction during the manufacturing process. The number of memory gate electrodes 230M included in the memory cells may be determined according to the capacity of the semiconductor device 10. According to an example embodiment, the number of upper and lower gate electrodes 230U and 230L may be one to two or more, respectively, and the upper and lower gate electrodes 230U and 230L may have a structure identical to and different from the memory gate electrodes 230M. In an example embodiment, erase gate electrodes may be further disposed below the upper gate electrodes 230U. Additionally, some of the gate electrodes 230, for example, the memory gate electrodes 230M adjacent to the upper or lower gate electrodes 230U and 230L, may be dummy gate electrodes, but example embodiments are not limited thereto.

The gate electrodes 230 may be disposed to be separated from each other in the Y-direction by separation regions MS extending continuously within the cell region R1 and the extension region R2. The gate electrodes 230 between a pair of separation regions MS may form one memory block BLK, but a range of the memory block BLK is not limited thereto. Some of the gate electrodes 230, for example, the memory gate electrodes 230M, may form one layer each within one memory block BLK.

The gate electrodes 230 may be vertically spaced apart from each other and stacked within the cell region R1 and the extension region R2, and may extend from the cell region R1 to the extension region R2 by different lengths. Thus, the gate electrodes 230 may form a staircase-shaped step structure in a portion of the extension region R2, for example, in the extension region R2. The gate electrodes 230 may also be disposed to have a step structure in the Y-direction. By the step structure, the gate electrodes 230 may extend to be longer than the gate electrode 230 in an upper portion, each of which may have regions in which upper surfaces thereof are exposed upwardly from the interlayer insulating layers 220 and other gate electrodes 230, and the upper regions may be referred to as pad regions. In each gate electrode 230, the pad region may be a region including an end of the gate electrode 230 in the X-direction. The pad region may correspond to one region of a gate electrode 230 disposed in an uppermost portion in each region, among the gate electrodes 230 included in the stack structures GS1 and GS2 within the extension region R2. The gate electrodes 230 may be respectively connected to the contact plugs 270 in the pad regions. The gate electrodes 230 may have an increased thickness in the pad regions.

The gate electrodes 230 may include a metal material, for example, tungsten (W). According to an example embodiment, the gate electrodes 230 may include polycrystalline silicon or a metal silicide material. According to example embodiments, the gate electrodes 230 may further include a diffusion barrier 231, and for example, the diffusion barrier 231 may include tungsten nitride (WN), tantalum nitride (TaN), titanium nitride (TiN), or combinations thereof.

The interlayer insulating layers 220 may be disposed between the gate electrodes 230 to form the stack structures GS1 and GS2. Similarly to the gate electrodes 230, the interlayer insulating layers 220 may also be spaced apart from each other in a direction, perpendicular to the lower surface of the first conductive layer 201 and the protective layer 251, and may be disposed to extend in the X-direction. The interlayer insulating layers 220 may include an insulating material such as silicon oxide or silicon nitride.

In example embodiments, thicknesses of the interlayer insulating layers 220 may not all be the same. For example, among the interlayer insulating layers 220, an uppermost interlayer insulating layer 223, the lowermost interlayer insulating layer 222, and an intermediate interlayer insulating layer 225 may have a greater thickness than the other interlayer insulating layers 220, but example embodiments are not limited thereto. The intermediate interlayer insulating layer 225 may be defined as interlayer insulating layers between the stack structures GS1 and GS2.

The separation regions MS may be disposed to extend in the X-direction through at least a portion of the gate electrodes 230. The separation regions MS may be disposed to be parallel to each other. The separation regions MS may penetrate through the entire stacked gate electrodes 230 and may be connected to a lower insulation layer 291. The separation regions MS may extend as one shape in the X-direction, but may extend intermittently in some regions or may be disposed only in some regions.

A separation insulating layer 264 may be disposed in the separation regions MS. The separation insulating layer 264 may have a shape in which a width thereof increases toward the first substrate 101 due to a high aspect ratio, but example embodiments are not limited thereto. A lower end of the separation insulating layer 264 may be in contact with the lower insulating layer 291, and an upper end may be included in a protruding portion protruding above an upper surface of the stack structures GS1 and GS2, and the protruding portion may be in contact with the etch stop structures 250. A first width W1 of an upper end of the separation regions MS in the Y-direction may be greater than a width of an upper end of each of the channel structures CH, but example embodiments are not limited thereto. The separation insulating layer 264 may not extend to the edge region EA, and may be disposed only within the cell region R1 and the extension region R2. As illustrated in FIG. 2, the separation regions MS may be formed so that side surfaces thereof have flat planes, but example embodiments are not limited thereto.

The insulation regions SS may extend in the X-direction between the separation regions MS adjacent to each other. The insulation regions SS may be disposed within a portion of the extension region R2 and the cell region R1. The insulating regions SS may penetrate through the upper gate electrode 230U disposed on an uppermost of the gate electrodes 230. As illustrated in FIG. 3B, the insulating regions SS may divide the upper gate electrode 230U in the Y-direction. However, the number of gate electrodes 130U separated by the upper separation regions SS may be varied in example embodiments.

The insulating regions SS may intersect a portion of the channel structures CH. The insulating regions SS may have a predetermined width in the Y-direction, and may extend to intersect a plurality of channel structures CH arranged in a zigzag shape in the X-direction. Accordingly, when the plurality of channel structures CH are arranged to have the same separation distance, the insulating regions SS may extend to intersect a row of channel structures CH at the same time. The insulating regions SS may be recessed into an upper portion of the channel structures CH, for example, a portion of the channel structure CH facing one gate electrode 230U, and thus, a portion of the channel structures CH may be removed. In this case, the channel structures CH may be recessed by a length shorter than a radius of the channel structure CH from a channel center axis [symbol] c to an inner wall of the channel hole. Accordingly, the insulating regions SS may not pass through the channel center axis [symbol] c of the channel structure CH, and may be disposed so that at least ½ of the channel structure CH remains on an upper surface thereof, but example embodiments are not limited thereto. The channel structures CH into which the insulating regions SS are recessed may be effective channel structures which actually function as memory cells, not dummy channel structures. Each of the insulating regions SS may include an upper separation insulating layer 268. The upper separation insulating layer 268 may include an insulating material, and may include, for example, silicon oxide, silicon nitride, or silicon oxynitride.

The channel structures CH may be disposed in rows and columns on the lower surface of the first conductive layer 201 of the cell region R1 and may be spaced apart from each other. The channel structures CH may be disposed in a zigzag shape in one direction in the X-Y plane. The channel structures CH may penetrate through the gate electrodes 230, and may extend in a vertical direction, perpendicular to the lower surface of the first conductive layer 201, for example, in the Z-direction, and may have a pillar shape, and may have an inclined side surface in which a width thereof increases as the channel structures CH get closer to the first conductive layer 201 depending on the aspect ratio.

Each of the channel structures CH may have a form in which a lower channel structure CH1 and an upper channel structure CH2 penetrating through the lower stack structure GS1 and the upper stack structure GS2 of the gate electrodes 230 are connected to each other, and may have a bent portion due to a difference or a change in width in the connection region. For example, the bent portion may be oblique with respect to the X-direction and the Y-direction.

As illustrated in an enlarged view of FIG. 4A, each of the channel structures CH may include a first portion within the stack structures GS1 and GS2 and a second portion protruding above the stack structures GS1 and GS2.

A channel layer 240 may be entirely disposed in the first portion and the second portion of the channel structure CH, and may be disposed up to an upper end of the second portion. The channel layer 240 may include a protrusion portion 240a disposed in the second portion of the channel structure CH and protruding and exposed upwardly of the stack structures GS1 and GS2, and a non-protrusion portion 240b disposed on the first portion of the channel structure CH. Protrusion lengths h1 of the second portions of the channel structures CH, the protrusion portions 240a of the channel layer 240, may not be the same as each other, but example embodiments are not limited thereto. The channel layer 240 may be formed in an annular shape in which a side surface surrounds a buried insulating layer 247 inside, but may also have a columnar shape such as a cylindrical or angular column without the buried insulating layer 247 according to an example embodiment. The protrusion portion 240a of the channel layer 240 may be covered with the first conductive layer 201 and may be in direct contact with the first conductive layer 201. The protrusion portion 240a may be formed to have a gentle slope with the non-protrusion portion 240b so that the annular shape is maintained as illustrated in FIG. 4A. The channel layer 240 may include a semiconductor material such as polycrystalline silicon or single-crystal silicon, and the semiconductor material may be an undoped material or a material including a P-type or N-type impurity.

In the channel structures CH, channel pads 249 may be disposed in a lower portion of the channel layer 240. The channel pads 249 may be disposed to cover a lower surface of the buried insulating layer 247 and may be electrically connected to the channel layer 240. The channel pads 249 may include, for example, doped polycrystalline silicon.

An information storage structure 245 may be disposed between the gate electrodes 230 and the channel layer 240. The information storage structure 245 may include a tunneling layer 241, a charge storage layer 242, and a blocking layer 243, which are sequentially stacked from a channel layer 240. The tunneling layer 241 may tunnel charges into the charge storage layer 242, and may include, for example, silicon oxide (SiO₂), silicon nitride (Si₃N₄), silicon oxynitride (SiON), or combinations thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-κ dielectric material, or combinations thereof. According to example embodiments, at least a portion of the information storage structure 245 may form a channel dielectric layer extending in a horizontal direction along the gate electrodes 230.

The information storage structure 245 may be removed from the upper portion of the stack structures GS1 and GS2 so that the protrusion portion 240a of the channel layer 240 is exposed to the outside in the second portion. Therefore, an upper portion of the information storage structure 245 may be in contact with the first conductive layer 201, and a side surface of the information storage structure 245 in the first portion may be disposed to surround the non-protrusion portion 240b of the channel layer 240.

The channel layer 240, the information storage structure 245, and the buried insulating layer 247 may be connected to each other between the upper channel structure CH2 and the lower channel structure CH1. As described above, a relatively thick intermediate interlayer insulating layer 225 may be disposed between the upper channel structure CH2 and the lower channel structure CH1.

The support structures 265 may be disposed in the extension region R2 and may have a structure identical to or similar to the channel structures CH, but may not perform an actual function in the semiconductor device 10. The support structures 265 may be disposed in rows and columns in the extension region R2. The support structures 265 may have a diameter equal to or smaller than a maximum diameter of the contact plugs 270. The shape, number, and/or gap of the support structures 265 may be different. The channel structures CH and the support structures 265 may have a circular or nearly circular shape, but are not limited thereto and in some example embodiments may have another shape, such as an oval shape. The support structures 265 may provide structural support to prevent deformation such as bending of the stack structures GS1 and GS2.

The contact plugs 270 may be connected to the contact regions of the gate electrodes 230 in gate pad regions of the extension region R2. The contact plugs 270 may penetrate through at least a portion of the upper capping layer 290 and may be connected to each of the contact regions of the gate electrodes 230 exposed upwardly. The contact plugs 270 may penetrate through the gate electrodes 230 below the contact regions and may be connected to the upper interconnection structures 271 and 272. The contact plugs 270 may be spaced apart from the gate electrodes 230 below the contact regions by the contact insulating layers 260. However, in some example embodiments, the contact plugs 270 may be disposed so as not to penetrate through the gate electrodes 230, in which case the contact plugs 270 may be connected to each of the contact regions of the gate electrodes 230 exposed upwardly.

The contact plugs 270 may have a shape corresponding to the channel structures CH or a shape corresponding to the separation region MS. Each of the contact plugs 270 may include an upper region penetrating through each of the stack structures GS1 and GS2, a lower region extending with the upper portion and disposed below the upper region. The lower region and the upper region may have an inclined side surface in which a width thereof decreases as the lower region and the upper region get close to the protective layer 251 in each of the stack structures GS1 and GS2 due to the aspect ratio, and may have a cylindrical shape.

As illustrated in FIG. 3A, each of the contact plugs 270 may have a horizontally expanded shape in the contact region. The contact plug 270 may include a vertical extension portion 270V extending in the Z-direction, and a horizontal extension portion 270H extending horizontally from the vertical extension portion 270V and contacting the gate electrode 230. The horizontal extension portion 270H may be disposed along a perimeter of the vertical extension portion 270V, and may be surrounded on an entire side surface by the gate electrode 230. A length from a side surface of the vertical extension portion 270V to an end of the horizontal extension portion 270H may be smaller than a length from a side surface of the vertical extension portion 270V to outer surfaces of the contact insulating layers 260. The contact plugs 270 may be spaced apart from the gate electrodes 230 below the contact regions, i.e., the gate electrodes 230 not electrically connected, by the contact insulating layers 260.

The contact plugs 270 may include a conductive material, and may include, for example, at least one of tungsten (W), copper (Cu), aluminum (Al), and alloys thereof. In some example embodiments, the contact plugs 270 may include a barrier layer extending along a side surface and a bottom surface thereof, or may have an air gap therein.

The contact insulating layers 260 may be disposed to surround side surfaces of each of the contact plugs 270 below the contact regions. The contact insulating layers 260 may be spaced apart from each other in the Z-direction around each of the contact plugs 270. The contact insulating layers 260 may be disposed on substantially the same level as the gate electrodes 230, respectively. The contact insulating layers 260 may include an insulating material, and may include, for example, silicon oxide, silicon nitride, or silicon oxynitride.

The external contact vias 275 may be connected to transmit an external signal to the first semiconductor structure S1 through the pad region 258 exposed to the outside and the upper interconnection structure 271 and 272 of the second semiconductor structure S2, in the edge region EA. The external contact vias 275 may penetrate through the upper capping layer 290 and may be connected to the pad region 258 exposed upwardly through upper studs 257.

The external contact vias 275 may have a shape corresponding to the channel structures CH or a shape corresponding to the contact plugs 270. Each of the external contact vias 275 may include a lower region and an upper region extending with the lower region and disposed above the lower region so as to have bent portions corresponding to shapes of the lower channel structure CH1 and the upper channel structure CH2 of the channel structures CH. The lower region and the upper region may have an inclined side surface in which a width thereof decreases as the lower region and the upper region get close to the protective layer 251 due to the aspect ratio, and may have a cylindrical shape. An upper width of the external contact vias 275 may have a size 1.5 to 3 times an upper width of the channel structure CH, but example embodiments are not limited thereto. The external contact vias 275 may include a conductive material, and may include, for example, at least one of tungsten (W), copper (Cu), aluminum (Al), or alloys thereof.

At least one etch stop structure 250 may be disposed within the cell region R1. Each of the at least one etch stop structures 250 may include a bar type or a line type extending in the X-direction.

Each of the at least one etch stop structures 250 may include a lower surface on the same level as a lower surface of the protective layer 251 and an upper surface on the same level as an upper surface of the protective layer 251.

The etch stop structures 250 may include the same material as the protective layer 251, and may be defined as a bar type structure identically stacked and deposited on an entire upper portion of the second semiconductor structure S2, and then patterned by an etching process.

The at least one etch stop structure 250 may include two short-side surfaces having a short length and two long-side surfaces having a long length between the upper surface and the lower surface, and at least one of the short-side surfaces may be connected to and integrated with the protective layer 251. All of the etch stop structures 250 may be connected to the protective layer 251, and may be connected thereto in boundaries between the cell region R1 and the extension region R2 and/or boundaries between the cell region R1 and the edge region EA.

Accordingly, the protective layer 251 may be defined as an insulating layer disposed on an upper portion of the stack structures GS1 and GS2 or the upper capping layer 290 in the extension region R2 and the edge region EA, and at least one of the etch stop structures 250 may be defined as an insulating structure disposed in an upper portion of the stack structures GS1 and GS2 within the cell region R1.

In FIGS. 1 to 4B, the etch stop structures 250 may be simultaneously connected to the protective layer 251 and integrated there with, but example embodiments are not limited thereto.

The etch stop structures 250 may be spaced apart from each other in the Y-direction in the cell region R1 and may extend parallel to each other, and may have substantially the same size and shape, but example embodiments are not limited thereto.

The etch stop structures 250 may be spaced apart from each other in the Y-direction by a first distance I1. The first distance I1 may be equal to or smaller than a critical distance, and the critical distance may be a maximum distance at which the buffer layer 205 is not dished during a planarization process. The critical distance may be, for example, in a range of 3 μm to 4 μm, but example embodiments are not limited thereto.

The etch stop structures 250 may be spaced apart from the channel structures CH. Specifically, at least one etch stop structure 250 may be spaced apart from the closest channel structures CH, among the channel structures CH, by at least a first distance d1 or more. The first distance d1 may be equal to a channel pitch, which is a center distance between the channel structures CH, but example embodiments are not limited thereto.

Each of the etch stop structures 250 may be spaced apart from the channel structure CH and may thus be disposed so that at least a portion thereof overlap the separation region MS. As illustrated in FIGS. 1 to 4B, each of the etch stop structures 250 may overlap the separation region MS within the cell region R1, and may be disposed so as to cover a protruding portion protruding above the upper end of the separation region MS, i.e., the upper surface of the stack structures GS1 and GS2. Accordingly, the separation region MS may not be exposed outside the etch stop structure 250 within the cell region R1.

Specifically, each of the etch stop structures 250 may be disposed so that a lower surface thereof has a second width W2 in the Y-direction, and the second width W2 may be larger than the first width W1 of the separation region MS. For example, the second width W2 may satisfy two to three times the first width W1, and may satisfy 300 nm to 500 nm, preferably 300 nm to 350 nm.

In this manner, one etch stop structure 250 may be disposed in the cell region R1 corresponding to each separation region MS, and the separation region MS may extend to the extension region R2, but an etch stop structure 250 may be integrated with the protective layer 251 in the extension region R2.

When a central axis of the first width W1 in the Y-direction of the separation region MS is defined as a first axis [symbol] 0, a central axis of the second width W2 in the Y-direction of the etch stop structure 250 thereon may be defined as a second axis [symbol] 1. The second axis [symbol] 1 and the first axis [symbol] 0 may be coaxial, but example embodiments are not limited thereto.

A separation distance between the second axis [symbol] 1 and the central axis [symbol] c of the closest channel structure CH may satisfy the first distance d1.

When the second portion of the channel structure CH protrudes upwardly from the stack structures GS1 and GS2 by the first length h1, a protruding portion of the separation region MS may protrude by a second length h2, and the second length h2 may be equal to or greater than the first length h1. In this case, the second length h1 may not be greater than 1.5 times the first length h1 and may have a length in a similar range.

Each etch stop structure 250 may have a third length h3 in the Z-direction, and may be substantially the same as the second width W2 in the Y-direction. The third length h3 may be greater than the first length h1 of the channel structure CH, and may be greater than the second length h2 which is a length of the protruding portion of the separation region MS. Accordingly, an upper surface of the separation region MS disposed inside may be spaced apart from an upper surface of the etch stop structure 250.

Each of the etch stop structures 250 may be provided so that widths of an upper surface and a lower surface thereof are substantially the same as each other. Accordingly, side surfaces of each of the etch stop structures 250 may be substantially perpendicular to the upper surface of the stack structures GS1 and GS2.

The third length h3 of the etch stop structure 250 may be 300 nm to 500 nm, preferably 300 nm to 350 nm, but example embodiments are not limited thereto.

In this manner, the etch stop structures 250 disposed to surround the separation region MS may be disposed within the cell region R1, so that each block BLK may have an isolated shape isolated by the etch stop structures 250 spaced apart from the protective layer 251.

The first conductive layer 201 and the second conductive layer 202 may be disposed on the stack structures GS1 and GS2 inside the blocks isolated by the etch stop structures 250 spaced apart from the protective layer 251.

The first conductive layer 201 may be disposed between a lower surface of the second conductive layer 202 and the stack structures GS1 and GS2 in the cell region R1. The first conductive layer 201 may include a semiconductor material. For example, the first conductive layer 201 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). The first conductive layer 201 may function as a common source line CSL of the semiconductor device 10. The first conductive layer 201 may include a silicon layer, and may include, for example, a silicon layer having an N-type conductivity type. For example, the first conductive layer 201 may be provided as a crystalline semiconductor layer or an epitaxial layer, such as a single-crystal silicon layer or a polycrystalline silicon layer, doped with impurities. As illustrated in an enlarged view of FIG. 4A, the first conductive layer 201 may cover the second portion of the channel structure CH and may be in direct contact with the protrusion portion 240a of the channel layer 240.

In the first conductive layer 201 disposed in each block, a bottom region entirely covering the stack structures GS1 and GS2 of each block may be provided as a plate layer, and the first conductive layer 201 may be disposed so that an upper surface of the bottom region has a flat surface. In each block, the first conductive layer 201 may be disposed so that the bottom region has a first thickness t1, and the first thickness t1 may be greater than the first length h1 of the protrusion portion 240a of the channel layer 240. For example, when the first length h1 of the protrusion portion 240a of the channel layer 240 satisfies 150 nm to 180 nm, the first thickness t1 of the first conductive layer 201 may satisfy 200 nm to 220 nm, which is greater than the length h1 of the protrusion portion 240 a, and the first conductive layer 201 may remain above the protrusion portion 240a.

In each block, an upper surface of a bottom region of the first conductive layer 201 may be disposed on a level lower than the upper surface of the etch stop structure 250, and a lower surface of the bottom region of the first conductive layer 201 may be disposed on a level equal to or lower than a lower surface of the etch stop structure 250.

The first conductive layer 201 may have a bottom region and a side region bent from the bottom region. Each side region of the first conductive layer 201 may be formed to be in contact with a side surface of the etch stop structure 250 and a side surface of the protective layer 251, and may be substantially perpendicular to an upper surface of the interlayer insulating layer 222, i.e., the lower surface of the bottom region of the first conductive layer 201, as illustrated in FIG. 4B. The bent side region of the first conductive layer 201 may have a thickness thinner than the bottom region within each block, but example embodiments are not limited thereto.

The second conductive layer 202 may be disposed along the first conductive layer 201. The second conductive layer 202 may have a thickness smaller than that of the first conductive layer 201 and may be a conductive layer in contact with the first conductive layer 201. The second conductive layer 202 may also include a bottom surface filling an interior of each block and a side surface bent from the bottom surface. The bottom surface and the side surface of the second conductive layer 202 may also have substantially the same thickness, unlike the first conductive layer 201, but example embodiments are not limited thereto.

A concave recess portion may be formed on an upper surface of a bottom surface of the second conductive layer 202 by a bending structure of the second conductive layer 202. That is, within each block surrounded by the etch stop structure 250 and the protective layers 251, a recess portion may be formed by the first conductive layer 201 and may also be formed by the second conductive layer 202 formed along the recess portion.

The second conductive layer 202 may include at least one of a metal-semiconductor compound, a metal-nitride, and a metal (e.g., tungsten (W), copper (Cu), aluminum (Al)). The second conductive layer 202 may be aligned vertically with the first conductive layer 201. The second conductive layer 202 may have a multilayer structure, but example embodiments are not limited thereto. For example, the second conductive layer 202 may include a layered structure of an ohmic contact layer, a conductive layer, and a diffusion barrier.

Within each block, the first and second conductive layers 201 and 202 may serve as a source layer and together form a source structure. The source structure may function as a common source line CSL of the semiconductor device 10.

A buffer layer 205 may be further formed within the recess portion of the second conductive layer 202 on the second conductive layer 202. The buffer layer 205 may protect the first and second conductive layers 201 and 202 when patterning the second conductive layer 202 and the first conductive layer 201. The buffer layer 205 may fill the recess portion of the second conductive layer 202, and an upper surface thereof may be coplanar with an upper surface of the etch stop structure 250 and an upper surface of the protective layer 251, and may be coplanar with upper ends of side surfaces of the first conductive layer 201 and the second conductive layer 202.

The buffer layer 205, the second conductive layer 202, and the first conductive layer 201 may be sequentially stacked, and may be a structure in which a thickness thereof is thinned by performing planarization through a chemical and mechanical polishing process. Accordingly, when viewed in the X-Y plane, the buffer layer 205, the second conductive layer 202, and the first conductive layer 201 may have a structure in which each block is be completely filled with the buffer layer 205, the second conductive layer 202 surrounds a periphery of the buffer layer 205 in a frame shape, and the first conductive layer 201 surrounds a periphery of the second conductive layer 202 in a frame shape.

Additionally, the etch stop structures 250 and the protective layer 251 surround a periphery of the first conductive layer 201.

The etch stop structure 250 may function as an etch stop layer in a chemical mechanical polishing process, and the planarization may be terminated on the upper surface of the etch stop structure 250, so that the upper surface of the etch stop structure 250 and upper ends of the buffer layer 205, the first conductive layer 201 and of the second conductive layer 202 may all form a coplanar surface. The buffer layer 205 may include an oxide, and may include, for example, silicon oxide, silicon nitride.

The upper insulating structure 210 may be disposed to cover both the common source line CSL and the protective layer 251.

The upper insulating structure 210 may include a first insulating layer 211 and a hydrogen supply layer 213. The first insulating layer 211 may cover the buffer layer 205, the etch stop structure 250, and the protective layer 251, and may be formed to have a flat upper surface, and may include an insulating material, and may include, for example, silicon oxide, silicon nitride, or silicon oxynitride. The hydrogen supply layer 213 may be H-rich SiN and may be formed of a material such as PE-SiN, and an annealing process may be performed in a state of being formed up to the hydrogen supply layer 213, thus forming a hydrogen path to the channel layer 240. For this purpose, the first insulating layer 211 may include TEOS, and HDP oxide may be included as the second insulating layer in the middle, but example embodiments are not limited thereto

The second semiconductor structure S2 may further include a source contact via 255 on the second conductive layer 202 of the common source line in each block and a source interconnection line 256 on the source contact via 255.

The source contact via 255 may penetrate through the buffer layers 205 and 211 so that the source interconnection line 256 on the second conductive layer 202 may be disposed on the first insulating layer 211.

Additionally, the upper studs 257 connecting the external contact vias 275 and the pad region 258 may be disposed in the edge region EA, and the pad region 258 may be disposed on the first insulating layer 211. The upper studs 257 may be disposed in a multilayer structure, and when the upper studs 257 are disposed in the multilayer structure, additional interconnection structures may be disposed therebetween, but example embodiments are not limited thereto. The first insulating layer 211 and the hydrogen supply layer 213 may be disposed to cover an edge of the pad region 258, and a central region of the pad region 258 may be provided in a state in which the central region may be exposed to the outside and connected to a wire or the like.

The passivation layer 215 may be disposed on an upper surface of the hydrogen supply layer 213. The passivation layer 215 may function as a layer protecting the semiconductor device 10. In an example embodiment, the passivation layer 215 has an opening OI in some regions, from which the pad region 258 connected to the outside may be defined. The passivation layer 215 may include an organic material, but may alternatively include at least one of silicon oxide or silicon carbide, and may function as a capping layer.

The upper interconnection structures 271 and 272 may electrically connect the gate electrodes 230 and the channel structures CH to the circuit elements 120. The upper interconnection structures 271 and 272 may include studs 272 connected to the channel structures CH, studs 272 connected to the contact plugs 270, and studs 272 connected to external contact vias 275. The studs 272 connected to the channel structures CH may be connected to the channel pads 249 of the channel structures CH. The studs 272 connected to the channel structure CH may be electrically connected to the channel layer 240 through the channel pads 249 of the channel structures CH in the cell region R1. In the extension region R2, the studs 272 may be connected to the contact plugs 270 connected to the gate electrode 230. The upper interconnection line 271 may be connected to the studs 272. The upper interconnection structures 271 and 272 may include a conductive material, and may include, for example, tungsten (W), copper (Cu), and aluminum (Al), and each of the components may further include a diffusion barrier including at least one of titanium (Ti), titanium nitride (TiN), tantalum (Ta), tantalum nitride (TaN), or tungsten nitride (WN). According to example embodiments, the number of layers and arrangement of studs 272 and upper interconnection lines 271 included in the upper interconnection structure 271 and 272 may be variously changed, and high energy and heat may be blocked by the protective layer 251 disposed on in an upper portion, so that diffusion of the metal material of the upper interconnection structure 271 and 272 does not proceed, thereby improving the reliability of the element.

The upper bonding structure 280 may be connected to the upper interconnection structure 271 and 272. For example, the studs 272 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection line 271. The upper bonding pad 284 may be connected to the upper bonding via 282. The upper bonding via 282 and the upper bonding pad 284 may include a conductive material, and may include, for example, tungsten (W), copper (Cu), and aluminum (Al), and each of the components may further include a diffusion barrier. The upper bonding insulating layer 286 may also function as a diffusion barrier of the upper bonding pad 284, and may include at least one of SiCN, SiO, SiN, SiOC, SiON, or SiOCN. The upper bonding insulating layer 286 may have a thickness thinner than a thickness of the upper bonding pad 284, but example embodiments are not limited thereto.

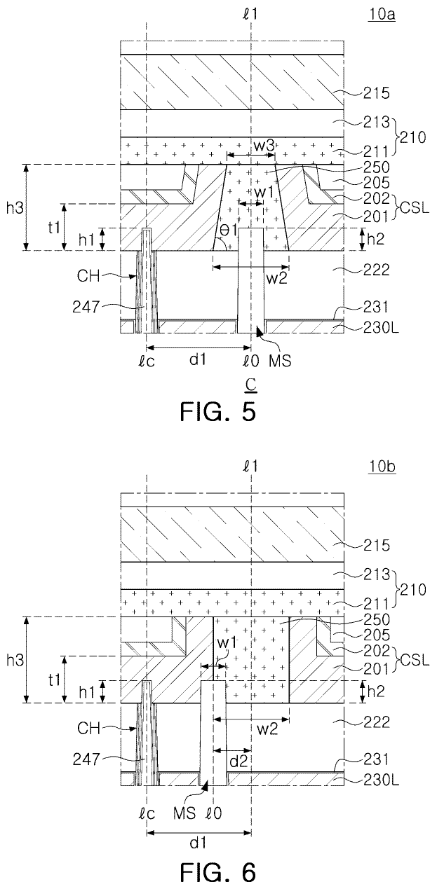

Hereinafter, example embodiments will be described with reference to FIGS. 5 to 7. FIGS. 5 to 7 are enlarged views of a semiconductor device according to example embodiments, and are enlarged views of region ‘C’ of FIG. 3B.

Referring to FIG. 5, a semiconductor device 10a is identical to that of FIG. 4B except for the shape of the etch stop structure 250 and the shape of the common source line CSL.

Specifically, in the semiconductor device 10a, at least one etch stop structure 250 extends in the X-direction and the etch stop structures 250 are spaced apart from each other in the Y-direction within the cell region R1.

Each of the etch stop structures 250 may include a side surface between an upper surface and a lower surface. The etch stop structures 250 may be provided so that the upper surface overlaps the lower surface, and an area of the upper surface may be smaller than an area of the lower surface. For example, the area of the etch stop structures 250 may gradually decrease from the lower surface to the upper surface, and the etch stop structures 250 may have the smallest area on the upper surface. Accordingly, when a width of the lower surface in the Y-direction has a second width W2, a width of the upper surface may have a third width W3 smaller than the second width W2.

The side surface may have an inclination with respect to the lower surface due to a difference between the second width W2 of the lower surface and the third width W3 of the upper surface. This inclination of the side surface may have a first angle θ1 with respect to the lower surface, and the first angle θ1 may be an acute angle greater than 70 degrees and less than 90 degrees.

By the inclination of the side surface of the etch stop structures 250 described above, the common source lines CSL within the block BLK surrounded by the etch stop structures 250 and the protective layers 251 adjacent to each other may be disposed so that a side region has an inclination from a bottom region.

That is, the side region of the first conductive layer 201 may be disposed to be inclined at an angle greater than 90 degrees from the bottom region, and the second conductive layer 202 on the first conductive layer 201 may also be disposed so that a side surface thereof is inclined at an obtuse angle from the bottom surface. Accordingly, a recess portion of the second conductive layer 202 may have a larger area toward an upper end thereof.

The recess portion of the second conductive layer 202 may be filled and the buffer layer 205 may be disposed therein, so that the buffer layer 205 may have a shape in which an area thereof increases toward an upper portion thereof.

In this manner, because a side surface of the etch stop structure 250 has an acute inclination, the common source line CSL and the buffer layer 205 inside may also be expanded so that an area thereof increases toward an upper portion thereof.

In this case, the etch stop structures 250 may also be disposed so that the protruding portions of the separation regions MS are buried inside.

Referring to FIG. 6, a semiconductor device 10b is identical to that of FIG. 4B except for the shape of the etch stop structure 250.

Specifically, in the semiconductor device 10b, at least one etch stop structure 250 extends in the X-direction within the cell region R1, and the etch stop structures 250 are spaced apart from each other in the Y-direction.

A center of a width of an upper surface of the etch stop structures 250 in the Y-direction may be defined as the second axis [symbol] 1, and a center axis of the closest channel structure CH of the etch stop structure 250 may be defined as the channel axis [symbol] c. In this case, each of the etch stop structures 250 may at least partially overlap the separation region MS.

Specifically, in the semiconductor device 10b of FIG. 6, the second axis [symbol] 1 of the etch stop structure 250 may be disposed to be offset by a second distance d2 in the Y-direction with respect to the first axis [symbol] 0 which is a center of a width of the lower separation region MS in the Y-direction.

In this case, at least a portion of the etch stop structure 250 may overlap with the separation region MS, and may be disposed so as to cover, for example, at least ½ of the protruding portion of the separation region MS. Alternatively, the etch stop structure 250 may be disposed so as to cover at least a portion of an upper surface of the separation region MS.

Even if the separation region MS overlapping the etch stop structure 250 is not coaxial, a separation distance between the second axis [symbol] 1 of the etch stop structure 250 and the channel axis [symbol] c of the closest channel structure CH may satisfy the first distance d1. Accordingly, the common source line CSL may sufficiently cover and contact an exposed channel layer 240a of the channel structure CH. Additionally, even if the etch stop structure 250 is partially offset from the separation region MS, the first separation distance I1 from the adjacent etch stop structure 250 may be formed to satisfy a critical distance or less, thereby maintaining the effect of preventing dishing during the planarization process.

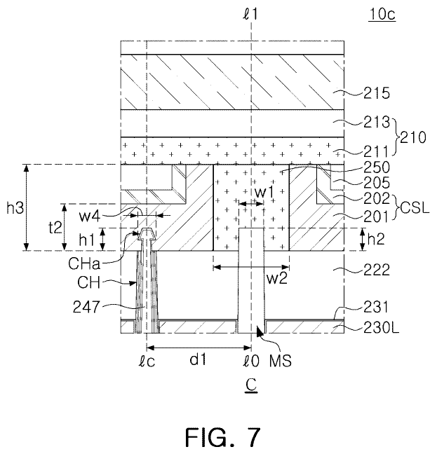

Referring to FIG. 7, a semiconductor device 10c is identical to that of FIG. 4A except that the shape of the protrusion portion 240a of each channel structure CH includes a head CH_a.

Specifically, the channel structure CH may further include a head CH_a having an expanded width in one end thereof. The head CH_a of the channel structure CH may have a width W4 greater than a width of the protrusion portion 240a of the channel layer 240. The head CH_a of the channel structure CH may be formed by a stopper for maintaining a depth of a channel hole uniformly during the manufacturing process, but example embodiments are not limited thereto.

The head CH_a may have different widths in the Z-direction, and for example, may have a width that becomes smaller toward an upper portion thereof, but example embodiments are not limited thereto, and the width of the upper portion and the width of the lower portion of the head CH_a may be formed to be the same. In this case, the width W4 of the lower portion of the largest head CH_a may be formed to be greater than a width of the non-protrusion portion 240b of the channel layer 240.

In this case, the width W4 of the head CH_a may satisfy about ½ to ⅗ of a separation distance between the channel structure CH and the adjacent channel structure CH.

Even if the head CH_a is formed, the stack structure of the first portion of the channel structures CH may be formed in the same manner as in FIG. 4A, and a height of the protrusion portion 240a may be the same as the first length h1, and the head CH_a may be formed to have a length smaller than the first length h1 of the protrusion portion 240a. The protrusion portion 240a of the channel layer 240 may be disposed on an outermost surface of the head CH_a, and an interior thereof may be filled with a buried insulating layer 247, or may be formed entirely with the channel layer 240 according to an example embodiment.

In this manner, when the head CH_a is formed on the protrusion portion 240a, a contact area between the first conductive layer 201 and the channel layer 240 is expanded by an expanded end, thereby increasing the amount of charge inflow.

Not only the channel structure CH, but also other vertical structures, such as the support structures 265 and the contact plugs 270, may include a head. The head of the contact plugs 270 may also be formed by a stopper for uniformly maintaining a depth of a contact hole during the manufacturing process, but example embodiments are not limited thereto.

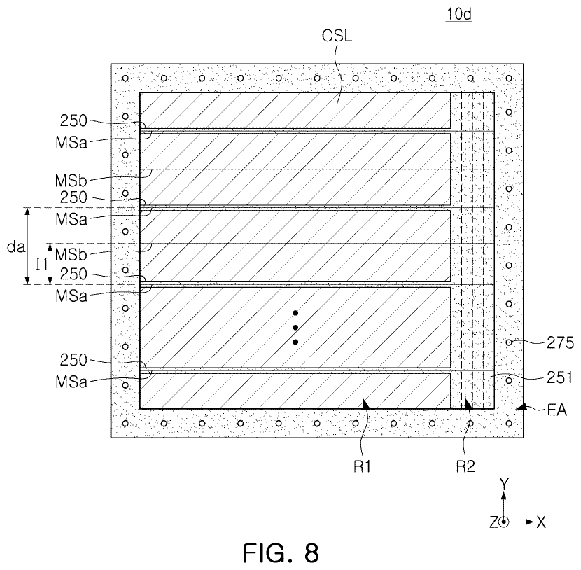

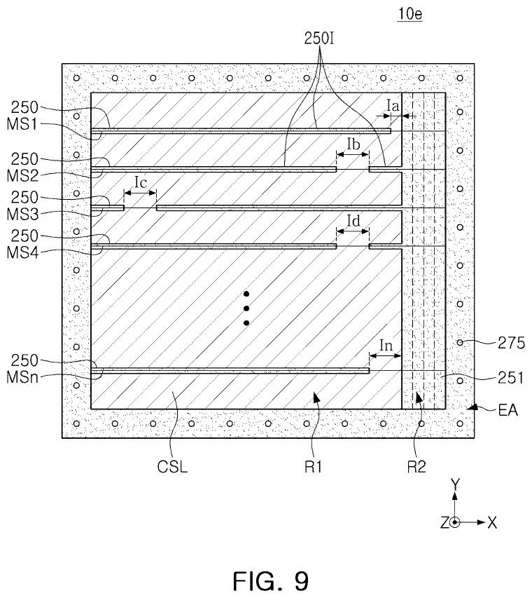

Hereinafter, example embodiments will be described with reference to FIGS. 8 and 9. FIGS. 8 and 9 are plan views of semiconductor devices according to example embodiments.

Referring to FIG. 8, a semiconductor device 10d is identical to the semiconductor device 10 of FIG. 1 except for an arrangement of a plurality of etch stop structures 250.

In the semiconductor device 10d of FIG. 8, the etch stop structure 250 extend in the X-direction within the cell region R1, and the etch stop structures 250 are spaced apart from each other in the Y-direction.

In this case, the etch stop structures 250 may overlap the separation regions MS within the cell region R1 in the Z-direction.

In this case, the separation regions MS may include first separation regions MSa overlapping the etch stop structures 250 and second separation regions MSb that do not overlap the etch stop structures 250. The shape and size of the first separation region MSa and the second separation region MSb may be substantially the same.

Specifically, the etch stop structures 250 may be disposed to cover upper ends and protruding portions of the first separation regions MSa in an upper portion of each of the first separation regions MSa. A second width W2 of the etch stop structures 250 in the Y-direction may be greater than the first width W1 of each of the first separation regions MSa in the Y-direction, and the third length h3 of the etch stop structures 250 in the Z-direction may be greater than the second length h2 of a protruding region exposed to the upper portion of the stack structures GS1 and GS2 of the first separation regions MSa, so that the first separation regions MSa may not be exposed to the outside of the etch stop structures 250.

Because the second separation regions MSb do not overlap the etch stop structures 250, the second separation regions MSb may be disposed to be in direct contact with the first conductive layer 201 of the common source line CSL within the cell region R1.

The first separation regions MSa and the second separation regions MSb may be disposed by alternating rows. Accordingly, the etch stop structures 250 covering the second separation region MSb may have a second separation distance da intersecting two blocks BLK within the cell region R1.

The second separation distance da may be greater than the first separation distance I1 of FIG. 1, but may be less than the critical distance. Accordingly, a common source line having a larger area than that of FIG. 1 may be formed to have a common plate shape on two blocks, but example embodiments are not limited thereto.

For example, the first separation region MSa may be disposed in every Kth separation region MS, and K may be 2 to 4. That is, within the range of the critical distance, the common source line CSL may be physically disposed continuously to include a plurality of blocks.

Accordingly, at least one second separation region MSb may be disposed in a lower portion of one common source line CSL, but the common source line CSL may be formed to have a flat bottom region by forming a sufficiently thick first conductive layer 201 covering a channel structure CH, and planarization by heat treatment.

Referring to FIG. 9, a semiconductor device 10e is identical to the semiconductor device 10 of FIG. 1 except for the arrangement of a plurality of etch stop structures 250.

In the semiconductor device 10e of FIG. 9, the etch stop structures 250 extend in the X-direction and at least some of the etch stop structures 250 are spaced apart from each other in the Y-direction within the cell region R1.

The etch stop structures 250 may overlap the separation regions MS in the Z-direction within the cell region R1.

On one separation region MS, the etch stop structures 250 may include at least one stop pattern 250I in which a short side surface thereof is exposed.

The etch stop structures 250 may include one stop pattern 250I, similarly to the etch stop structure 250 on the separation region MS of a first row, and the stop pattern 250I may not be connected to the protective layer 251 of the extension region R2 and may be spaced apart from the protective layer 251 by a first gap Ia in boundaries between the cell region R1 and the extension region R2. The first gap Ia may be smaller than the critical distance.

A side surface of the stop pattern 250I may be exposed within the cell region R1 by the first gap Ia between the stop pattern 250I and the protective layer 251.

The etch stop structures 250 may include a plurality of stop patterns 250I spaced apart from each other, similarly to the etch stop structures 250 on the separation regions MS of second to fourth rows.

A plurality of stop patterns 250I on one separation region MS may have separation distances of a second gap Ib, a third gap Ic, and a fourth gap Id, and short side surface thereof may be spaced apart from each other. In this case, the separation distances of the stop patterns 250I of each row may be different from each other, but may be equal to or smaller than the critical distance.

The separation distances between the stop patterns 250I on the separation regions MS adjacent to each other in the Y-direction may be offset so as not to overlap each other in the Y-direction. In this case, “being offset” does not denote that middle value of the separation distances do not match, but denotes that the second gap Ib and the third gap Ic do not overlap each other at all in the Y-direction, and the third gap Ic and the fourth gap Id do not overlap each other at all in the Y-direction. In this case, the first gap Ia may also not overlap the second gap Ib at all in the Y-direction. In this manner, because the separation distances between each of the stop patterns 250I do not overlap each other in the Y-direction, dishing that may occur between the separation distances may be prevented.

The semiconductor device 10e of FIG. 9 may be formed so that at least some of the etch stop structures 250 in the cell region R1 have a separation distance along the X-direction, and thus, the common source lines CSL disposed on each block may be physically connected to each other.

That is, because the first conductive layer 201 is formed continuously along the separation distance and the second conductive layer 202 and the buffer layer 205 are disposed on the first conductive layer 201, even if the planarization is advanced up to the etch stop structure 250, the common source lines CSL disposed in each block may have a structure in which the common source lines CSL are integrated to be physically/electrically connected to each other along a space of the separation distance.

Accordingly, an electrical connection of the common source lines CSL of each block through the upper interconnection structures 271 and 272 in an upper portion may be physically completed in a lower portion, while securing structural stability.

In this case, each etch stop structure 250 may not be disposed on all the separation regions MS, and may be disposed only on some of the separation regions MSa, as in FIG. 8.

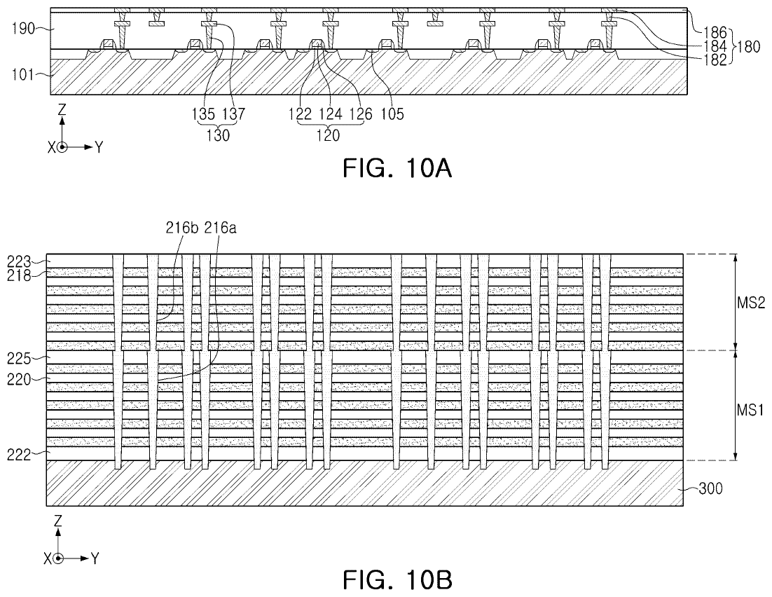

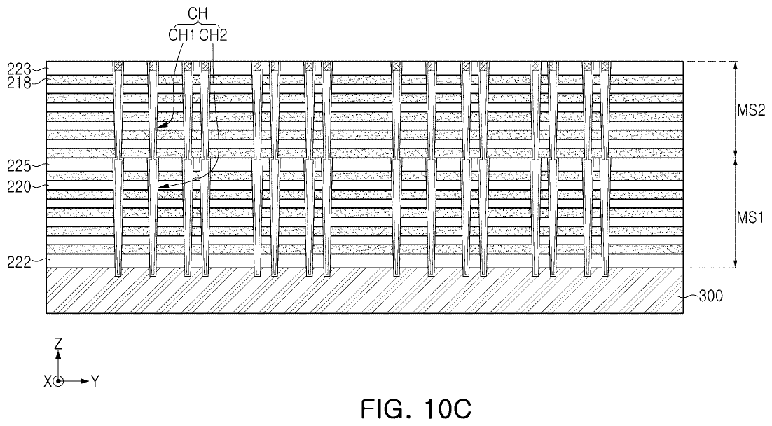

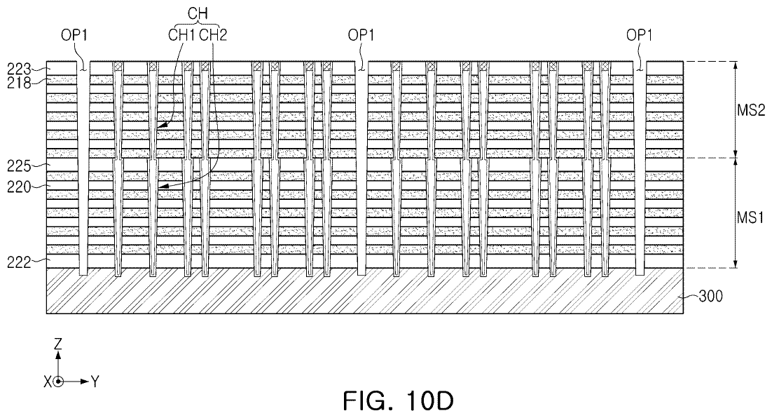

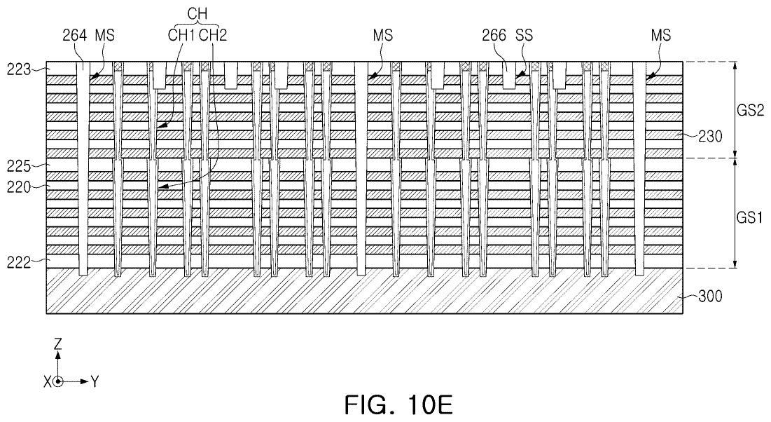

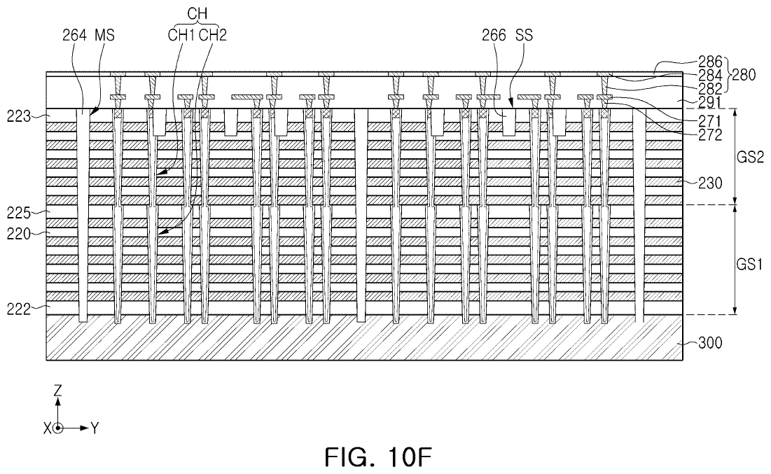

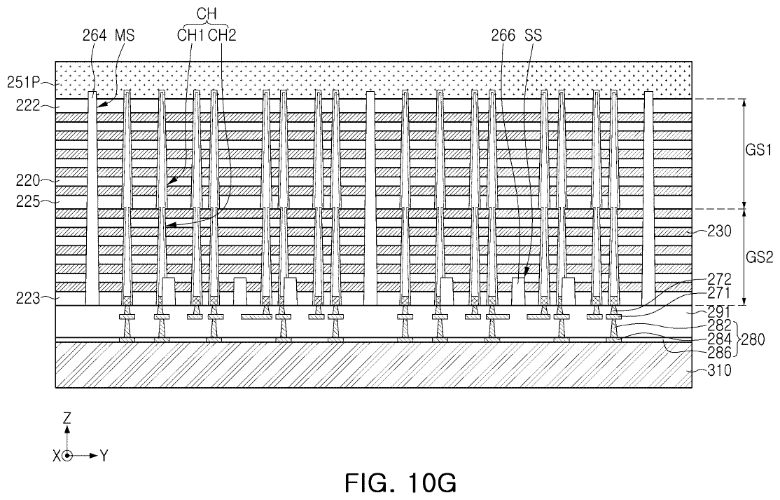

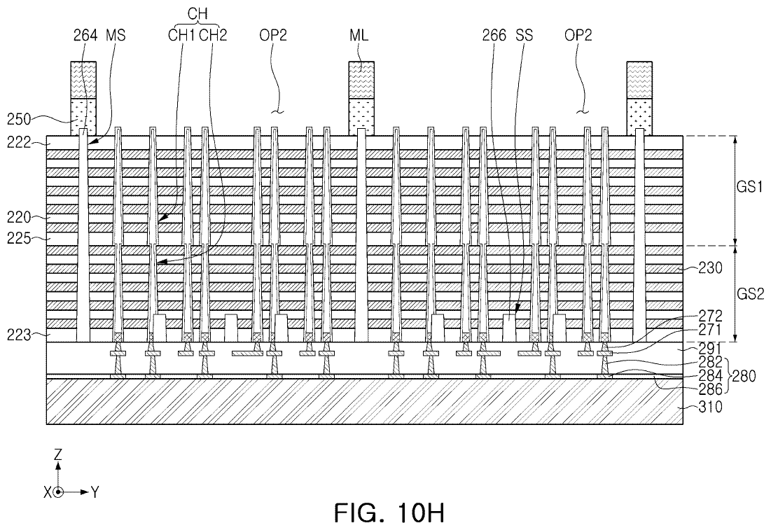

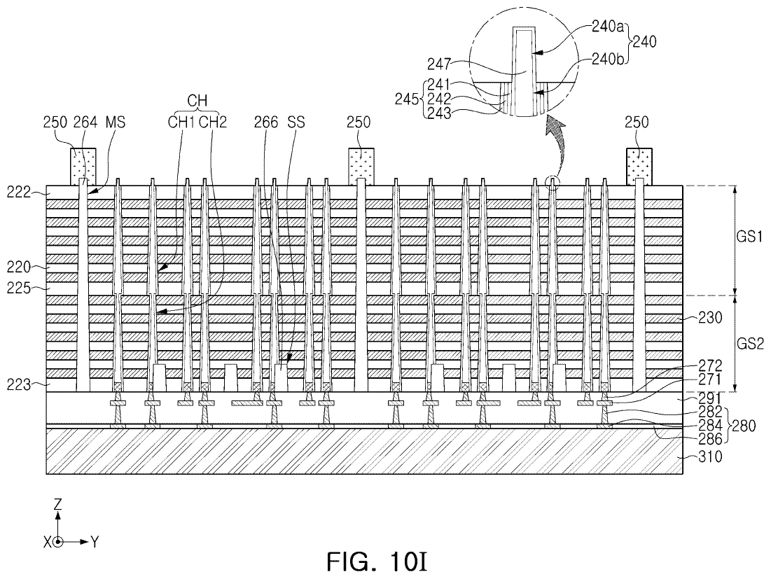

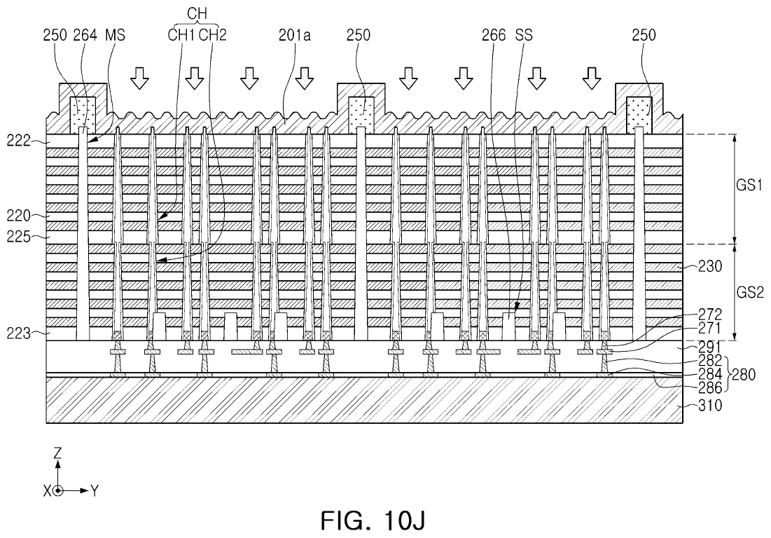

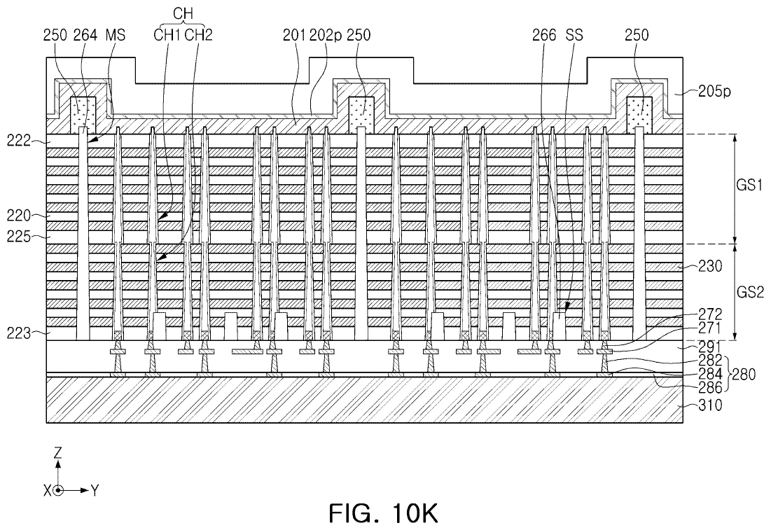

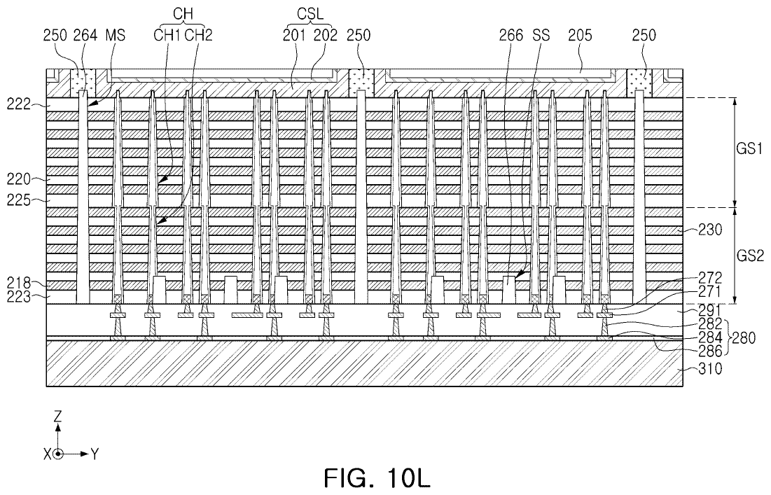

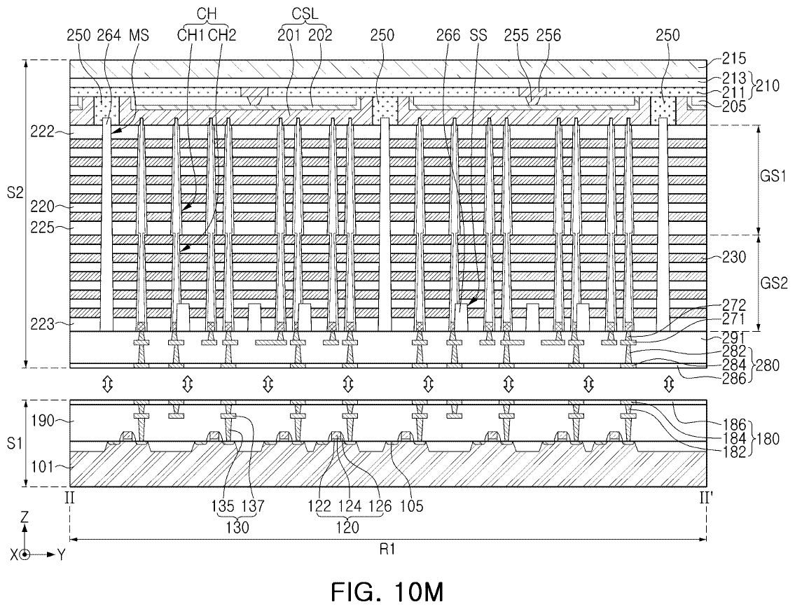

FIGS. 10A to 10M are schematic cross-sectional views illustrating a method of manufacturing a semiconductor device according to example embodiments. FIGS. 10A to 10M illustrate regions corresponding to FIG. 3B.

Referring to FIG. 10A, a first semiconductor structure (S1: PERI) including circuit elements 120, a lower interconnection structure 130, a lower bonding structure 180 and a lower capping layer 190, which form a peripheral circuit region PERI, may be formed on a first substrate 101.

Element isolation layers 110 may be formed in the first substrate 101, and a circuit gate dielectric layer 122 and a circuit gate electrode 124 may be sequentially formed on the first substrate 101. The element isolation layers 110 may be formed, for example, by a shallow trench isolation (STI) process. The circuit gate dielectric layer 122 may be formed on the first substrate 101, and the circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but example embodiments are not be limited thereto. Spacer layers 126 may be formed on both sidewalls of the circuit gate dielectric layer 122 and the circuit gate electrode 124, and impurities may be injected into an active region of the first substrate 101 on both sides of the circuit gate electrode 124 to form source/drain regions 105.

Among the lower interconnection structures 130, the lower contact plugs 135 may be formed by forming a portion of the lower capping layer 190, etching and removing the portion thereof, and then filling the removed portion with a conductive material. The lower interconnection lines 137 may be formed, for example, by depositing the conductive material and then patterning the conductive material.

Among the lower bonding structures 180, the lower bonding vias 182 may be formed by forming a portion of the lower capping layer 190, etching and removing the portion thereof, and then filling the removed portion with the conductive material. The lower bonding pads 184 may be formed, for example, by depositing the conductive material and then patterning the conductive material. The lower bonding structures 180 may be formed, for example, by a deposition process or a plating process. The lower bonding insulating layer 186 may be formed by covering a portion of an upper surface and a side surface of the lower bonding pad 184, and then performing a planarization process until the upper surface of the lower bonding pad 184 is exposed.

The lower capping layer 190 may be formed of a plurality of insulating layers. The lower capping layer 190 may be a portion in each operation of forming the lower interconnection structure 130 and the lower bonding structure 180. As a result, the first semiconductor structure S1, which is a peripheral circuit region PERI, may be formed.

Referring to FIG. 10B, a manufacturing process of a second semiconductor structure (S2: CELL) may begin.

Referring to FIG. 10B, the manufacturing process of the second substrate structure (S2: CELL) may begin. On a base substrate 300 (SUB), sacrificial insulating layers 218 and interlayer insulating layers 220 may be alternately stacked to form molded structures MS1 and MS2, and sacrificial vertical structures may be formed in positions in which each vertical structure is formed.

The lower molded structure MS1 may be formed on the base substrate 300 at a height at which the first channel structures CH1 are disposed.

The base substrate 300 may include a semiconductor material, and may include, for example, a group IV semiconductor, a group III-V compound semiconductor, or a group II-VI compound semiconductor.

The sacrificial insulating layers 218 may be layers in which at least a portion thereof is replaced with a portion of the gate electrodes 230 through a subsequent process. The sacrificial insulating layers 218 may be formed of a different material from the interlayer insulating layers 220. For example, the interlayer insulating layer 220 and the uppermost, intermediate, and lowermost interlayer insulating layers 222, 223 and 225 may be made of at least one of silicon oxide or silicon nitride, and the sacrificial insulating layers 218 may be formed of a different material from that of the interlayer insulating layer 220 selected from silicon, silicon oxide, silicon carbide, and silicon nitride. In example embodiments, thicknesses of the interlayer insulating layers 220 may not all be the same. Additionally, the thicknesses of the interlayer insulating layers 220 and the sacrificial insulating layers 218 and the number of films included therein may be variously changed from those illustrated.

The interlayer insulating layers 220 and the sacrificial insulating layers 218 included in the lower molded structure MS1 are alternately stacked on the base substrate 300.

The gate pad region may be formed by repeatedly performing a photolithography process and an etching process on the sacrificial insulating layers 218 and the interlayer insulating layers 220. The gate pad regions may be formed in the extension regions R2, and may be formed to include a region in which upper sacrificial insulating layers 218 extend to be shorter than lower sacrificial insulating layers 218. In the gate pad region, asymmetrical step structures may be formed so that upper surfaces and ends of a plurality of sacrificial insulating layers 218 are exposed upwardly. However, in example embodiments, the specific shape of the gate pad region may be variously changed. Sacrificial insulating layers 218 may be further formed on the step structures of the gate pad regions so that the sacrificial insulating layers 218 disposed in an uppermost portion in each region have a relatively thick thickness.

When forming a channel hole for forming vertical sacrificial structures 216a and 216b, a stop structure may be first formed to uniformly maintain a depth at which the channel hole is recessed into the base substrate 300.

A stop structure may be formed in a position in which the channel hole is formed in the base substrate 300 using a material that has etching selectivity with the base substrate 300 for the anisotropic etching, and the material may be, for example, a metal material such as tungsten (W). When the channel hole is formed in a state in which the stop structure formed in each channel hole, the channel hole may not be formed below the stop structure due to the stop structure. Then, the stop structure may be removed through the channel hole, and depending on the shape of the stop structure, a channel structure CH having the head CH_a as illustrated in FIG. 7 may be formed.

Next, an upper capping layer 290 covering the lower molded structure MS1 may be formed, and first vertical sacrificial layers 216a penetrating through the lower molded structure MS1 may be formed.

The first vertical sacrificial layers 216a may be formed in a position corresponding to a lower portion of the lower channel structures CH1 in the cell region R1. The first vertical sacrificial layers 216a may be formed by forming holes to penetrate through the lower molded structure MS1, depositing a sacrificial layer material in the holes, and performing a planarization process. The holes may include holes corresponding to the channel structures CH, the support structures 265, the contact plugs 270, and the external contact vias 275. The vertical sacrificial layers including the first vertical sacrificial layers 216a may include, for example, at least one of TiN or polycrystalline silicon.

Next, the sacrificial insulating layers 218 and the interlayer insulating layers 220 included in the upper molded structure MS2 may be alternately stacked on the lower molded structure MS1, a staircase-shaped step structure may be formed, an upper capping layer 290 may be formed on an edge region and a step structure, and second vertical sacrificial layers 216b may be formed.

Each component of the upper molded structure MS2 may be formed in the same manner as a formation method of the lower molded structure MS1.

The second vertical sacrificial layers 216b may be formed to be connected to the first vertical sacrificial layers 216a, respectively. The second vertical sacrificial layers 216b may be formed by depositing the same material as the first vertical sacrificial layers 216a, for example, polycrystalline silicon. Additionally, the vertical sacrificial layers for the support structure 265, the vertical sacrificial layers for the contact plugs 270, and the vertical sacrificial layers for the external contact vias 275 may all be formed by depositing the same material, for example, polycrystalline silicon.

As illustrated in FIG. 10C, channel structures CH penetrating through the molded structures MS1 and MS2 of the sacrificial insulating layers 218 and the interlayer insulating layers 220 may be formed on the base substrate 300.

The channel structures CH may be formed by forming upper holes on the vertical sacrificial layers 216a and 216b, and then, removing the vertical sacrificial layers 216a and 216b to form hole-shaped channel holes, and filling the channel holes with a plurality of layers. The plurality of layers may include an information storage structure 245, a channel layer 240, a buried insulating layer 247, and a channel pad 249. The upper channel holes of the channel holes may be formed by anisotropically etching the upper stack structure of the sacrificial insulating layers 218 and the interlayer insulating layers 220 using a separate mask layer. The lower channel holes of the channel holes may be formed by removing the vertical sacrificial layer exposed through the upper channel holes.

Due to heights of the molded structures MS1 and MS2, sidewalls of the channel structures CH may not be perpendicular to an upper surface of the base substrate 300. The channel structures CH may be formed to recess a portion of the base substrate 300 according to the depth of the channel hole.

The information storage structure 245 may be formed to have a uniform thickness. The information storage structure 245 may be formed in whole or in part in this operation, and a portion extending vertically to the base substrate 300 along the channel structures CH may be formed in this operation. The channel layer 240 may be formed on the information storage structure 245 within the channel structures CH. The buried insulating layer 247 may be formed to fill the channel structures CH and may be an insulating material. The channel pad 249 may be formed of a conductive material, for example, polycrystalline silicon. The support structures 265 (see FIG. 2) of the extension region R2 may also be formed in a similar manner. Specifically, the support structures 265 may be formed by removing vertical sacrificial layers to form support holes, and then filling the support holes with a support insulating layer. In this case, the vertical sacrificial layer in a region corresponding to the contact plugs 270 may be removed, and contact insulating layers and contact sacrificial layers may be formed.

As illustrated in FIG. 10D, separation openings OP1 may be formed in a region corresponding to the separation regions MS. The separation openings OP1 may be formed to penetrate through the molded structures MS1 and MS2 in the Z-direction in a line type intersecting the cell region R1 and the extension region R2 in the X-direction. Each of the separation openings OP1 may be formed to open a portion of the base substrate 300.

As illustrated in FIG. 10E, wet etching may be performed through the separation openings OP1 to selectively remove the sacrificial insulating layers 218 with respect to the interlayer insulating layers 220, thereby forming gate electrodes 230.

The gate electrodes 230 may be formed by depositing a conductive material in regions from which the sacrificial insulating layers 218 are removed. The conductive material may include a metal, polycrystalline silicon, or a metal silicide material. In some example embodiments, a portion of the gate dielectric layer may be formed first before forming the gate electrodes 230.

After forming the gate electrodes 230, gate separation insulating layers 264 may be formed within the separation openings OP1 formed to correspond to the separation regions MS, and at least one upper gate electrode 230U may be etched to form insulating regions SS. In this case, contact plugs 270 may be formed in the extension region R2.

Referring to FIG. 10F, upper interconnection structures 271 and 272 including studs 272 and upper interconnection lines 271 may be formed, and upper bonding structures 280 may be formed.

In the cell region R1, the studs 272 may be formed to be connected to the channel structures CH. In the extension region R2, the studs 272 may be formed to be connected to the contact plugs 270. Additionally, the studs 272 connected to the external contact vias 275 in the extension region R2 may also be formed. Each of the studs 272 may be connected to the upper interconnection lines 271 upward and downward, and may be connected in multiple layers through separate plugs.

Next, the upper bonding structure 280 may be formed in a similar manner to forming the lower bonding structure 180. Accordingly, the second semiconductor structure S2, which is a memory cell structure CELL, may be formed. However, in the manufacturing process of the semiconductor device 10, the second semiconductor structure S2 may further include the base substrate 300.

Referring to FIG. 10G, the stack structures GS1 and GS2 on which the base substrate 300 is formed may be transferred to a carrier substrate 310 and may be inverted so that the base substrate 300 is exposed upwardly.

Specifically, when the stack structures GS1 and GS2 are inverted so that the upper bonding structure 280 is in contact with the carrier substrate 310, the channel structures CH, the separation regions MS, the contact plugs 270 and the external contact vias 275, below the base substrate 300 exposed upwardly, may be disposed in reverse so that a width thereof increases downwardly. Next, the base substrate 300 may be removed, and the lowermost interlayer insulating layer 222 and lowermost ends of the channel structures CH, the separation regions MS and the contact plugs 270 may be formed in a protruding state. In this case, a separate layer may not be formed between the base substrates 300 as an etch-preventing film for the channel structures CH, so that the removal of the base substrate 300 may be performed at a significantly fast speed. Next, a preliminary protective layer 251P may be formed on an uppermost surface of the exposed stack structures GS1 and GS2. The preliminary protective layer 251P may be formed to cover the entire semiconductor device 10 and to have a predetermined thickness, and the predetermined thickness may be formed to have a third length h3 corresponding to a height of the etch stop structure 250, and may be 300 nm to 500 nm. The preliminary protective layer 251P may be entirely subject to plasma CVD by applying PE-SiN thereto, and in this case, the plasma CVD may be performed in a hydrogen atmosphere, thereby forming an H-rich SiN layer including a large amount of hydrogen.

As illustrated in FIG. 10H, the preliminary protective layer 251P may be patterned to form an opening OP2 defining each block within the cell region R1.

The opening OP2 may be formed until an upper surface of the lowermost interlayer insulating layer 222 in a lower portion is exposed, and the openings OP2 may be formed between line-type etch stop structures 250 so that the etch stop structure 250 of FIG. 2 remains within the cell region R1. The opening OP2 may be formed by selectively removing the preliminary protective layer 251P by a mask pattern ML, and may be formed to have an inclined side surface so that a width of an upper portion of the opening OP2 is greater than a width of a lower portion thereof, or may be formed vertically. A side surface of the etch stop structure 250 may be formed without an inclination by dry etching, and when the etch stop structure 250 is disposed on the separation regions MS, the etch stop structures 250 in a lower portion of the mask pattern ML may be etched vertically not to be recessed inwardly along a side surface thereof, thereby safely supporting a layer structure to be stacked thereafter.

Next, as illustrated in FIG. 10I, the information storage structure 245 on the second portion of the channel structure CH exposed within the opening OP2 may be removed. The information storage structure 245 may be removed by a photolithography process and an etching process such as wet etching and/or dry etching. As a result, within the opening, the second portion of the channel structure CH protruding onto the stack structures GS1 and GS2 may be exposed to the channel layer 240 so that the protrusion portion 240a may be disposed. Accordingly, when a subsequent process is performed, the channel layer 240 of the second portion may be in direct contact with the first conductive layer 201. In this case, an etching process for continuous removal of the oxide film, nitride film, and oxide film may be performed, and a portion of the uppermost interlayer insulating layer 222 including the oxide may be etched together, so that an upper surface of the uppermost interlayer insulating layer 222 within the opening OP2 may be lowered on a level lower than that of the lower surface of the etch stop structure 250 and the lower surface of the protective layer 251, but example embodiments are not limited thereto.

As illustrated in FIG. 10J, the first conductive layer 201 may be formed to cover the entire semiconductor device 10. The first conductive layer 201 may be formed by depositing a semiconductor layer, specifically, a crystalline silicon layer, for example, a polycrystalline silicon layer 201a. In this case, the polycrystalline silicon layer 201a formed entirely on an upper surface of the semiconductor device may be formed to have an inflection along the channel structures CH protruding within the opening OP2. Accordingly, a thickness of the polycrystalline silicon layer 201a above the protective layer 251 and a thickness of the polycrystalline silicon layer 201a within the opening may be different from each other.

In this case, a Melting laser annealing (MLA) process may be performed to activate the polycrystalline silicon layer 201a. The MLA process is a process in which impurities in the polycrystalline silicon layer 201a are diffused and crystals are recrystallized through laser annealing, and is performed by a high-temperature and high-energy laser, and is performed simultaneously for the entire semiconductor device. During this MLA process, the extension region R2 and the edge region EA in which the protective layer 251 is formed may prevent energy and heat from being transmitted downwardly because the protective layer 251 absorbs high energy and heat. Accordingly, because the interconnection structures 271 and 272 including copper disposed below the stack structures GS1 and GS2 are not affected, defects in which copper metals are diffused may be prevented. Through this MLA process, when the polycrystalline silicon layer 201a is melted and then crystallized again, an upper surface of the polycrystalline silicon layer 201a within an opening having an inflection may be formed to be flat to form the first conductive layer 201. Accordingly, the upper surface of the first conductive layer 201 within the cell region R1 may be flat, and a thickness thereof may have a value greater than a thickness of the first conductive layer 201on the etch stop structure 250.

As illustrated in FIG. 10K, a preliminary second conductive layer 202P may be formed on the first conductive layer 201 and a preliminary buffer layer 205P may be formed continuously. Specifically, the preliminary second conductive layer 202P may be formed by continuously depositing an ohmic contact layer, a conductive metal layer, and a diffusion barrier, and a thickness of the conductive metal layer may be formed to have a significantly large value. The preliminary second conductive layer 202P may be covered entirely, and the preliminary buffer layer 205P may be conformally formed, and an oxide film, for example, a silicon oxide film, may be formed as the preliminary buffer layer 205P. The preliminary second conductive layer 202P and the preliminary buffer layer 205P may also be deposited and disposed on the entire semiconductor device 10.

As illustrated in FIG. 10L, the first conductive layer 201, the second conductive layer 202, and the buffer layer 205 may be disposed within a block, which is an opening OP2 of the cell region R1, and may be etched so as not to be expanded to the extension region R2 and the edge region EA. The etching of the first conductive layer 201, the second conductive layer 202, and the buffer layer 205 may be performed by a planarization process, for example, chemical mechanical polishing (CMP), and the polishing may be performed so that the planarization is terminated on upper surface of the etch stop structures 250 and the protective layer 251 having the same height.

In this manner, all of the first conductive layer 201, the second conductive layer 202 and the buffer layer 205 may be etched through the planarization process, so that an upper surface of the buffer layer 205, upper ends of the first and second conductive layers 201 and 202, and the upper surface of the etch stop structure 250 may form a coplanar surface.

Additionally, by the planarization, the etch stop structure 250 may be disposed with a separation distance equal or to less than the critical distance, so that dishing of the buffer layers 205 disposed over a relatively wide area may be prevented, thereby improving physical reliability.

As illustrated in FIG. 10M, a hydrogen supply layer 213 may be continuously formed on the first insulating layer 211 to form an upper insulating structure 210, and a passivation layer 215 may be formed to complete the upper structure. Specifically, a hydrogen supply layer 213 may be further formed on the first insulating layer 211, and the first insulating layer 211 to the hydrogen supply layer 213 may be opened to form a source contact via 255, and then a source interconnection line 256 connected to the source contact via 255 may be formed within the hydrogen supply layer 213. A plurality of common contact vias 255 may be formed within a single semiconductor device to simultaneously transmit a common source voltage to a common source line CSL, and the source interconnection line 256 for this purpose may be connected to each other. A passivation layer 215 may be formed to cover the common source line CSL. The passivation layer 215 may be planarized by a polishing process such as a grinding process or a chemical mechanical polishing process. A portion of the passivation layer 215 may be removed through a subsequent process to form an input/output pad area 258, but example embodiments are not limited thereto.

The first semiconductor structure S1, which is a peripheral circuit structure PERI, and the second semiconductor structure S2, which is a memory cell structure CELL, may be bonded to each other.

The first semiconductor structure S1 and the second semiconductor structure S2 separated from the carrier substrate 310 may be connected by bonding the lower bonding pad 184 and the upper bonding pad 284 by applying pressure thereto. The lower bonding insulating layer 186 and the upper bonding insulating layer 286 may be bonded and connected by applying pressure thereto. The second semiconductor structure S2 may be bonded on the first semiconductor structure S1 so that the upper bonding pad 284 may face downwardly. The first semiconductor structure S1 and the second semiconductor structure S2 may be directly bonded without the intervention of an adhesive such as a separate adhesive layer.

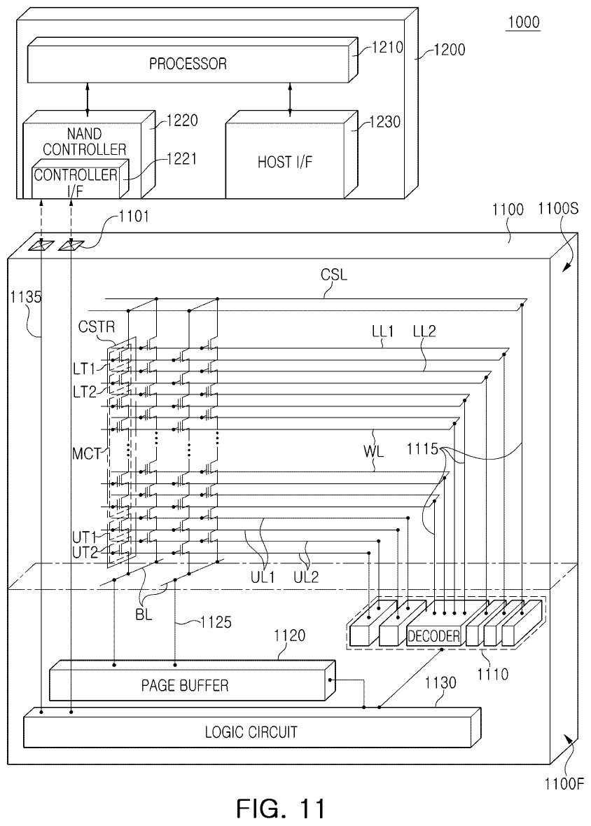

FIG. 11 is a schematic diagram illustrating a data storage system including a semiconductor device according to example embodiments.

Referring to FIG. 11, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device, including one or more semiconductor devices 1100.

The semiconductor device 1100 may be a nonvolatile memory device, and may be, for example, a NAND flash memory device consistent with the above description provided with reference to FIGS. 1 to 9. The semiconductor device 1100 may include a first semiconductor structure 1100F and a second semiconductor structure 1100S on the first semiconductor structure 1100F. According to example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second gate upper lines UL1 and UL2, first and second gate lower lines LL1, LL2, and memory cell strings CSTR between the bit line BL and the common source line CSL.

In the second semiconductor structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

According to example embodiments, the upper transistors UT1 and UT2 may include string select transistors, and the lower transistors LT1 and LT2 may include ground select transistors. The gate lower lines LL1, LL2 may be gate electrodes of the lower transistors LT1 and LT2, respectively. The word lines WL may be gate electrodes of memory cell transistors MCT, and the gate upper lines UL1 and UL2 may be gate electrodes of upper transistors UT1 and UT2, respectively.

According to example embodiments, the lower transistors LT1 and LT2 may include ground select transistors LT1 and LT2 connected in series. The upper transistors UT1 and UT2 may include string select transistors UT1 and UT2 connected in series.

The common source line CSL, the first and second gate lower lines LL1, LL2, the word lines WL, and the first and second gate upper lines UL1 and UL2 may be electrically connected to the decoder circuit 1110 through first interconnection lines 1115 extending from the first semiconductor structure 1100F to the second semiconductor structure 1100S. The bit lines BL may be electrically connected to the page buffer 1120 through second interconnection lines 1125 extending from the first semiconductor structure 1100F to the second semiconductor structure 1100S.

In the first semiconductor structure 1100F, the decoder circuit 1110 and the page buffer 1120 may perform a control operation for at least one selected memory cell transistor, among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 via an input/output interconnection line 1135 extending from the first semiconductor structure 1100F to the second semiconductor structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 treating communication with the semiconductor device 1100. Through the NAND interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When a control command is received from the external host through the host interface 1230, the processor 1210 may control the semiconductor device 1100 in response to the control command.

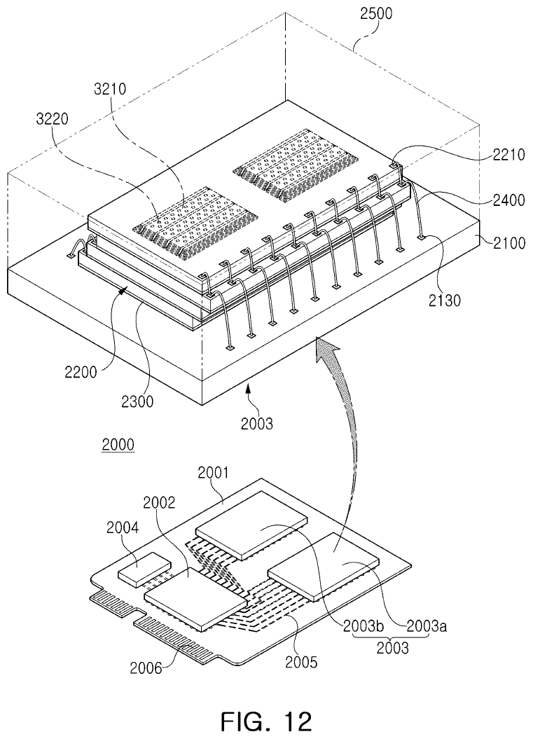

FIG. 12 is a perspective view schematically illustrating a data storage system including a semiconductor device according to an example embodiment.

Referring to FIG. 12, a data storage system 2000 according to an example embodiment of the present disclosure may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on a communication interface between the data storage system 2000 and the external host. According to example embodiments, the data storage system 2000 may communicate with the external host according to any one of the following interfaces: Universal Serial Bus (USB), Peripheral Component Interconnect Express (PCI-Express), Serial Advanced Technology Attachment (SATA), M-Phy for Universal Flash Storage (UFS). According to example embodiments, the data storage system 2000 may operate by power supplied from the external host through a connector 2006. The data storage system 2000 may further include a Power Management Integrated Circuit (PMIC) distributing the power supplied from the external host to the controller 2002 and the semiconductor package 2003.

The controller 2002 may write data to the semiconductor package 2003 or read data from the semiconductor package 2003, and may improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a kind of cache memory, and may provide a space for temporarily storing data in a control operation for the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 11, and may be a region including the pad area 258 of FIG. 3A. Each of the semiconductor chips 2200 may include gate stack structures 3210 and channel structures 3220. Each of the semiconductor chips 2200 may include the semiconductor device described above with reference to FIGS. 1 to 9.

According to example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through-silicon via (TSV), instead of a connection structure 2400 in a bonding wire manner.

According to example embodiments, the controller 2002 and the semiconductor chips 2200 may be included in one package. According to an example embodiment, the controller 2002 and the semiconductor chips 2200 may be mounted on a separate interposer substrate different from a main substrate 2001, and the controller 2002 and semiconductor chips 2200 may be connected to each other by interconnection lines formed on the interposer substrate.

While aspects of example embodiments have been particularly shown and described, it will be understood that various changes in form and details may be made therein without departing from the spirit and scope of the following claims.

What is claimed is:

1. A semiconductor device, comprising:
a first semiconductor structure comprising a first substrate, circuit elements on the first substrate, a lower interconnection structure connected to the circuit elements, and a lower bonding structure connected to the lower interconnection structure; and
a second semiconductor structure on the first semiconductor structure,
wherein the second semiconductor structure comprises:
a stack structure comprising interlayer insulating layers and gate electrodes stacked along a first direction, within a first region and a second region;
an upper interconnection structure below the stack structure;
an upper bonding structure connected to the upper interconnection structure and bonded to the lower bonding structure;
a channel structure comprising a first portion penetrating the stack structure along the first direction and a second portion extending upwardly from the first portion within the first region;
etch stop structures in contact with an upper portion of the stack structure, the etch stop structures extending along a second direction, perpendicular to the first direction, and spaced apart along a third direction, perpendicular to the first direction and the second direction, within the first region;
a common source conductive layer on the stack structure between the etch stop structures within the first region, the common source conductive layer being connected to the second portion of the channel structure; and
a buffer layer on the common source conductive layer.

2. The semiconductor device of claim 1, further comprising a protective layer on the stack structure within the second region,
wherein the protective layer and the etch stop structures comprise a common material.

3. The semiconductor device of claim 2, wherein the protective layer and the etch stop structures comprise nitride.

4. The semiconductor device of claim 2, wherein an upper surface of the etch stop structures is on a same level as an upper surface of the protective layer.

5. The semiconductor device of claim 2, wherein at least one of the etch stop structures extends in the first region along the second direction, and comprises an end connected to the protective layer.

6. The semiconductor device of claim 2, wherein the common source conductive layer comprises a bottom region on the stack structure and a side region bent from the bottom region along any one of side surfaces of the etch stop structures and a side surface of the protective layer, and
wherein a thickness of the bottom region is greater than a thickness of the side region.

7. The semiconductor device of claim 6, wherein an upper surface of the buffer layer and an upper end of a side region of the common source conductive layer form a coplanar surface.

8. The semiconductor device of claim 1, wherein the common source conductive layer comprises:
a first conductive layer in contact with the second portion of the channel structure; and
a second conductive layer above the first conductive layer along the first conductive layer and comprising a different material from the first conductive layer, and
wherein the buffer layer is on the second conductive layer.

9. The semiconductor device of claim 1, wherein an upper surface of the buffer layer and an upper surface of the etch stop structures are on a same level.

10. The semiconductor device of claim 1, wherein the etch stop structures are spaced apart by a reference distance or less along the third direction, and
wherein the reference distance ranges of 3 μm to 4 μm.

11. The semiconductor device of claim 10, wherein separation distances of the etch stop structures along the third direction correspond to a common distance.

12. The semiconductor device of claim 1, wherein the etch stop structures comprise stop patterns spaced apart along the second direction.

13. The semiconductor device of claim 1, wherein the channel structure is one among a plurality of channel structures,
wherein each of the etch stop structures is spaced apart from a closest channel structure, among the plurality of channel structures, by a first distance or more, and
wherein the first distance is a channel pitch of the plurality of channel structures.

14. A semiconductor device, comprising:
a stack structure comprising interlayer insulating layers and gate electrodes stacked along a first direction, within a first region and a second region;
separation regions penetrating the stack structure along the first direction, the separation regions extending along a second direction, perpendicular to the first direction, and spaced apart along a third direction, perpendicular to the second direction, within the first region and the second region;
a channel structure penetrating the stack structure along the first direction, within the first region;
etch stop structures on the stack structure, the etch stop structures extending along the second direction within the first region;
a common source conductive layer on the stack structure between the etch stop structures and connected to a channel layer of the channel structure, within the first region; and
a buffer layer on the common source conductive layer and comprising an insulating material,
wherein an upper surface of the buffer layer is on a same level as an upper surface of the etch stop structures.

15. The semiconductor device of claim 14, wherein in the first region, one of the etch stop structures covers at least a portion of one of the separation regions.

16. The semiconductor device of claim 15, wherein a width of the etch stop structures along the third direction is greater than a width of the separation regions along the third direction, and
wherein a length of the etch stop structures along the first direction is greater than a protruding length of the separation regions along the first direction protruding above the stack structure.

17. The semiconductor device of claim 15, wherein regions in the separation regions that protrude above the stack structure are completely covered with the etch stop structures within the first region.

18. The semiconductor device of claim 15, wherein at least a portion of one of the separation regions is exposed from an etch stop structure, among the etch stop structures, within the first region and is in contact with the common source conductive layer.

19. The semiconductor device of claim 14, further comprising a protective layer in a plate shape on the stack structure, within the second region,
wherein the protective layer and the etch stop structures comprise a common material, and
wherein an upper surface of the protective layer and an upper surface of the etch stop structures form a coplanar surface.

20. A semiconductor device, comprising:
a stack structure comprising interlayer insulating layers and gate electrodes stacked along a first direction, within a first region and a second region;
separation regions penetrating the stack structure along the first direction, the separation regions extending along a second direction, perpendicular to the first direction, and spaced apart along a third direction, perpendicular to the second direction, within the first region and the second region;
a channel structure penetrating the stack structure along the first direction, within the first region;
etch stop structures on the stack structure, the etch stop structures extending along the second direction within the first region;
a protective layer on the stack structure within the second region; a common source conductive layer on the stack structure between the etch stop structures and connected to a channel layer of the channel structure, within the first region; and
a buffer layer on the common source conductive layer and comprising an insulating material,
wherein an upper surface of the common source conductive layer is on a same level as an upper surface of the etch stop structures, and
wherein at least one of the etch stop structures comprises an end connected to the protective layer and extends along the second direction from the protective layer.
